(19) United States
(12) Patent Application Publication
(10) Pub. No.: US 2025/0374521 A1
(43) Pub. Date: Dec. 4, 2025

(54) SEMICONDUCTOR STRUCTURE HAVING A MEMORY STRUCTURE AND METHOD OF MANUFACTURING THE SAME

(71) Applicant: NANYA TECHNOLOGY CORPORATION, NEW TAIPEI CITY (TW)

(72) Inventor: KUO-HUI SU, NEW TAIPEI CITY (TW)

(21) Appl. No.: 18/733,103

(22) Filed: Jun. 4, 2024

(51) Int. Cl. H10B 12/00

(52) U.S. Cl. CPC H10B 12/33; H10B 12/05

(57) ABSTRACT

The present disclosure provides a semiconductor structure and a method of manufacturing the semiconductor structure. The semiconductor structure includes a data storage unit disposed in a first dielectric layer; a word line disposed in a second dielectric layer over the first dielectric layer; an array of conductive pads disposed over the second dielectric layer; a bit line disposed over the conductive pads; a third dielectric layer disposed over the second dielectric layer; and a fourth dielectric layer disposed over the third dielectric layer.

### TECHNICAL FIELD

The present disclosure relates to a semiconductor structure and a method for manufacturing the semiconductor structure. In particular, the present disclosure includes a semiconductor memory structure and a method for fabricating the semiconductor memory structure.

### DISCUSSION OF THE BACKGROUND

As the semiconductor industry has progressed into advanced technology process nodes in pursuit of greater device performance and density, it has reached an advanced precision of photolithography. In order to reduce device sizes, the dimensions of elements and distances between elements need to be proportionally reduced. However, with the reductions in the dimensions of the elements and the distances between elements, challenges of precise control of the dimensions and the distances have arisen.

One issue with the reduced sizes of semiconductor devices is planarity of the devices across a semiconductor wafer. In order to maintain good uniformity across semiconductor device levels, the component layers are required to achieve high flatness uniformity in the single semiconductor wafer and across different semiconductor wafers. In addition, to achieve better electrical performance and to enhance reliability of semiconductor devices under a reliable planarization scheme, a spacer structure along a bit line having an air gap and a dielectric isolation structure including an air gap between a pair of bit lines are provided.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor structure. The semiconductor structure includes: a data storage unit disposed in a first dielectric layer; a word line disposed in a second dielectric layer over the first dielectric layer; an array of conductive pads disposed over the second dielectric layer; a bit line disposed over the conductive pads; a third dielectric layer disposed over the second dielectric layer; and a fourth dielectric layer disposed over the third dielectric layer.

In some embodiments, the semiconductor structure further comprises a spacer structure disposed on sidewalls of the bit line, wherein the spacer structure includes a second air gap.

In some embodiments, the second air gap is sandwiched by a first spacer dielectric layer and a vertical portion of a second spacer dielectric layer, and the second air gap is sealed by a seal layer.

In some embodiments, the second air gap is formed by disposing a spacer layer in a first air gap between the first spacer dielectric layer and the second spacer dielectric layer.

In some embodiments, the first air gap is formed by removing a sacrificial layer disposed between the first spacer dielectric layer and the second spacer dielectric layer.

In some embodiments, the semiconductor structure further comprises a fifth dielectric layer disposed on the bit line, and disposed over the third dielectric layer and the fourth dielectric layer; and a sixth dielectric layer disposed between a pair of the fifth dielectric layers over the third dielectric layer and the fourth dielectric layer.

In some embodiments, the seal layer includes a linear layer and a planar layer, wherein the linear layer is disposed over the spacer structure, a horizontal portion of the second spacer dielectric layer, the fifth dielectric layer and the sixth dielectric layer, and the planar layer is disposed over the linear layer.

In some embodiments, the semiconductor structure further comprises a conductive via extending through the seal layer and the fifth dielectric layer, wherein the conductive via is connected to a conductive pad over the third and fourth dielectric layers.

In some embodiments, a width of the second air gap is less than a width of the first air gap.

In some embodiments, the spacer layer is made of a material same as a material of the first dielectric layer and the second dielectric layer.

One aspect of the present disclosure provides a semiconductor structure. The semiconductor structure includes: a data storage unit disposed in a first dielectric layer; a word line disposed in a second dielectric layer over the first dielectric layer; an array of conductive pads disposed over the second dielectric layer; a bit line disposed over the conductive pads; a third dielectric layer disposed over the second dielectric layer; a fourth dielectric layer disposed over the third dielectric layer; a fifth dielectric layer disposed on the bit line and disposed over the third dielectric layer and the fourth dielectric layer; a sixth dielectric layer disposed between a pair of the fifth dielectric layers, and disposed over the third dielectric layer and the fourth dielectric layer; and a conductive line disposed in the second dielectric layer.

In some embodiments, the semiconductor structure further comprises a dielectric isolation structure disposed in the sixth dielectric layer, wherein the dielectric isolation structure includes a liner layer enclosing an air gap.

In some embodiments, the dielectric isolation structure is transformed by a reinforcement pillar disposed in the sixth dielectric layer.

In some embodiments, the reinforcement pillar is made of an energy-removable material.

In some embodiments, the energy-removable material includes a thermal decomposable material.

In some embodiments, the energy-removable material includes a base material and a decomposable porogen material, wherein the base material includes hydrogen silsesquioxane (HSQ), methylsilsesquioxane (MSQ), porous polyarylether (PAE), porous SiLK, or porous silicon oxide (SiO₂), and the decomposable porogen material includes a porogen organic compound.

In some embodiments, the semiconductor structure further comprises a capping dielectric layer formed over the reinforcement pillar.

In some embodiments, the capping dielectric layer is made of silicon oxide, silicon nitride, silicon oxynitride, or the like.

In some embodiments, the sixth dielectric layer is made of silicon oxide, silicon nitride, silicon oxynitride, phosphosilicate glass (PSG), borophosphosilicate glass (BPSG), low-k dielectric material, and/or other applicable dielectric materials.

In some embodiments, the semiconductor structure further comprises a conductive via electrically coupled to the conductive line.

One aspect of the present disclosure provides a method for fabricating a semiconductor structure. The method includes: providing a substrate including a first region and a second region adjacent to the first region; forming a first layer over the first region and the second region of the substrate, wherein the first layer comprises: a first dielectric layer across the first region and the second region of the substrate, and a data storage unit disposed in the first dielectric layer; forming a second layer on the first layer and over the first region and the second region of the substrate, wherein the second layer comprises: a second dielectric layer across the first region and the second region of the substrate, and a word line disposed in the second dielectric layer; and forming a third layer on the second layer and over the first region and the second region of the substrate, wherein the third layer comprises: a third dielectric layer disposed over the second layer and disposed over the first region and the second region of the substrate, a fourth dielectric layer disposed over the second layer, a fifth dielectric layer disposed over the fourth dielectric layer over the second region of the substrate, a sixth dielectric layer disposed between a pair of the third dielectric layers, a bit line disposed below the third dielectric layer, a conductive layer disposed below the bit line, and a conductive pad disposed between the bit line and the conductive pad.

In some embodiments, the method further comprises forming a trench in the sixth dielectric layer over the first region of the substrate; and forming a reinforcement pillar by depositing an energy-removable material in the trench.

In some embodiments, the method further comprises forming a capping dielectric layer over the reinforcement pillar, the third dielectric layer and the sixth dielectric layer; and performing a thermal process to transform the reinforcement pillar into a dielectric isolation structure.

In some embodiments, the method further comprises forming a conductive via penetrating through the capping dielectric layer and the third dielectric layer over the second region of the substrate, wherein the conductive via is connected to a conductive pad over the fourth and fifth dielectric layers.

In some embodiments, the dielectric isolation structure includes a liner layer enclosing an air gap.

In some embodiments, the energy-removable material includes a thermal decomposable material.

In some embodiments, the sixth dielectric layer is made of silicon oxide, silicon nitride, silicon oxynitride, phosphosilicate glass (PSG), borophosphosilicate glass (BPSG), low-k dielectric material, and/or other applicable dielectric materials.

In some embodiments, the capping dielectric layer is made of silicon oxide, silicon nitride, silicon oxynitride, or the like.

In some embodiments, the conductive via includes a material same as a material of the bit line.

In some embodiments, the conductive via is made of tungsten, or other conductive materials such as copper, aluminum, silver, gold, titanium, titanium nitride, tantalum, tantalum nitride, and alloys thereof.

Through the proposed semiconductor structure and a method for manufacturing the semiconductor structure of the present disclosure, the material layers of the semiconductor structure can be planarized with high planarity, and the electrical performance and reliability can be further enhanced. The device quality uniformity can thus be improved with minimized additional cost of the process change.

In addition, in the semiconductor structure provided in this disclosure, an air gap is disposed in the spacer structure along the bit line, and a dielectric isolation structure including an air gap is disposed between a pair of bit lines. The semiconductor structure can provide better electrical performance and enhance reliability for semiconductor devices. In addition, the method for fabricating the semiconductor structure can minimize additional cost in manufacturing.

The foregoing has outlined rather broadly the features and technical advantages of the present disclosure in order that the detailed description of the disclosure that follows may be better understood. Additional features and advantages of the disclosure will be described hereinafter and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims. The disclosure should also be understood to be coupled to the figures' reference numbers, which refer to similar elements throughout the description. It should be noted that, in accordance with the standard practice in the industry, various features are not drawn to scale. In fact, the dimensions of the various features may be arbitrarily increased or reduced for clarity of discussion.

FIGS. 1A, 1B, 1C, 1D, 1E, 1F, 1G, 1H, 1I, 1J, 1K, 1L, 1M, 1N, 1O, 1P, 1Q, 1R, 1S, 1T, 1U, 1V, 1W, 1X, 1Y, 1Z, 1AA and 1AB are schematic cross-sectional views of intermediate stages of a method of forming a semiconductor structure, in accordance with some embodiments of the present disclosure.

FIG. 2 is a schematic top view of a semiconductor structure, in accordance with various embodiments of the present disclosure.

FIGS. 3A, 3B, 3C, 3D, 3E, 3F, 3G, 3H, 3I and 3J are schematic cross-sectional views of intermediate stages of a method of forming a semiconductor structure, in accordance with various embodiments of the present disclosure.

FIGS. 3K, 3L, 3M, 3N and 3O are schematic cross-sectional views of intermediate stages of a method of forming a semiconductor structure, in accordance with various embodiments of the present disclosure.

FIGS. 4A, 4B and 4C show schematic flowcharts of a method of manufacturing a semiconductor structure, in accordance with some embodiments of the present disclosure.

### DETAILED DESCRIPTION

Embodiments, or examples, of the disclosure illustrated in the drawings are now described using a specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It should be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another element, component, region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limiting to the present inventive concept. As used herein, the singular forms “a,” “an” and “the” are intended to include the plural forms as well, unless the context clearly indicates otherwise. It should be understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the deviation normally found in the respective testing measurements. Also, as used herein, the terms “about,” “substantial” or “substantially” generally mean within 10%, 5%, 1% or 0.5% of a given value or range. Alternatively, the terms “about,” “substantial” or “substantially” mean within an acceptable standard error of the mean when considered by one of ordinary skill in the art. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “about,” “substantial” or “substantially.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

The terms “couple” or “connect” used throughout the present disclosure refers to physical or electrical linkage between two or more objects. These objects may also be referred to as being “coupled” or “connected” through exchange of data or information. These “coupled” or “connected” objects may be in direct contact in some cases or in indirect contact through other intervening objects.

Embodiments of the present disclosure discuss a semiconductor structure formed of a plurality of memory cells and a method of forming a semiconductor structure. In some embodiments, each memory cell is formed of a transistor comprised of a word line, a bit line, a source line, and channel layer, and a data storage unit electrically coupled to the transistor. The transistor may be used to control access operations, e.g., read and write operations, of the data storage unit. In some embodiments, the channel layer is electrically coupled to the bit line through a landing pad. In accordance with comparative embodiments, the methods of forming an array of landing pads over an array of channel layers are generally performed by forming a dielectric layer over the array of channel layers, followed by etching the dielectric layer to form vias. Conductive materials are deposited in the vias to form the array of landing pads. In order to improve the performance of the memory cell, in accordance with some embodiments, the order of forming the array of landing pads and the dielectric layer is interchanged. However, in some examples, a height uniformity of the landing pads may not be maintained within a predetermined specification during a subsequent planarization operation, and electrical properties of the landing pads may not be ensured. The device reliability of the memory cells is thus compromised.

To address the abovementioned issues, an etch stop layer is introduced to protect the landing pads during the planarization process. The planarization process can be compatible with conventional process recipes, and the height uniformity of the landing pads can thus be maintained. Therefore, the landing pads can be formed with enhanced reliability, and the memory cell having the new structure can be manufactured with minimized defects.

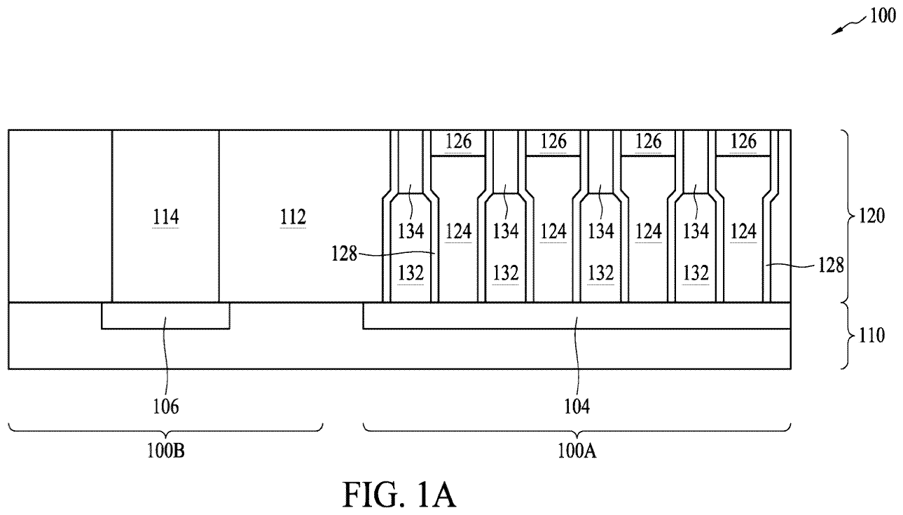

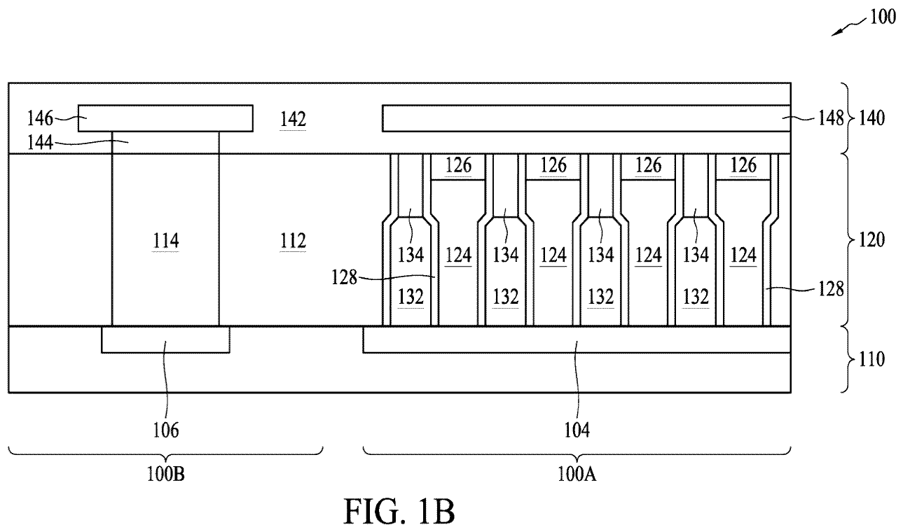

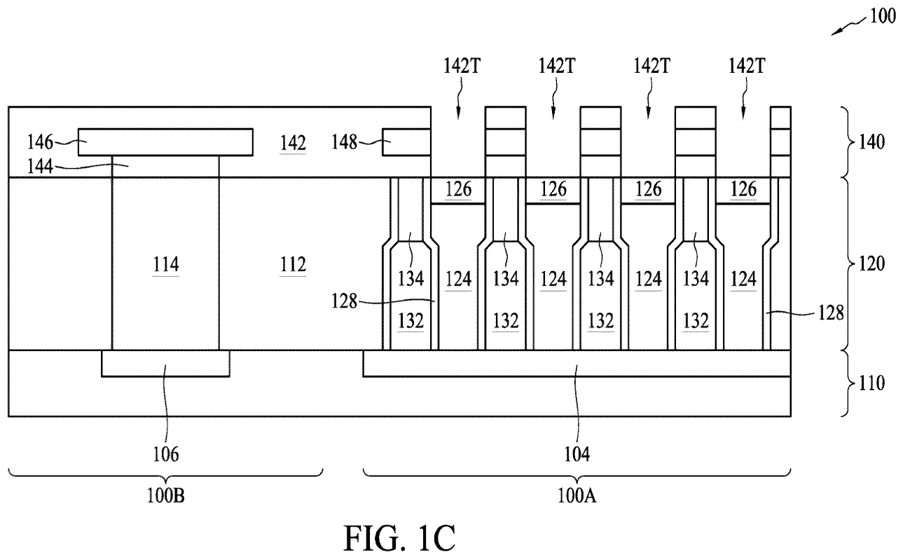

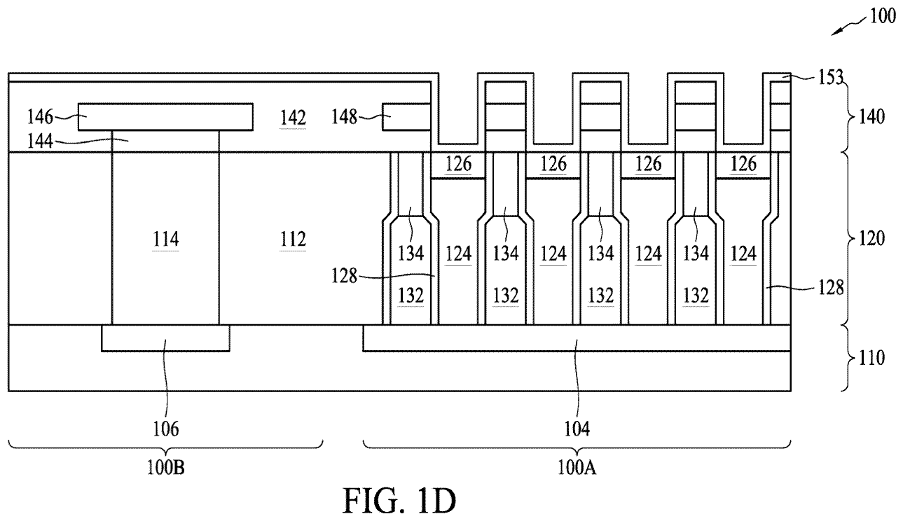

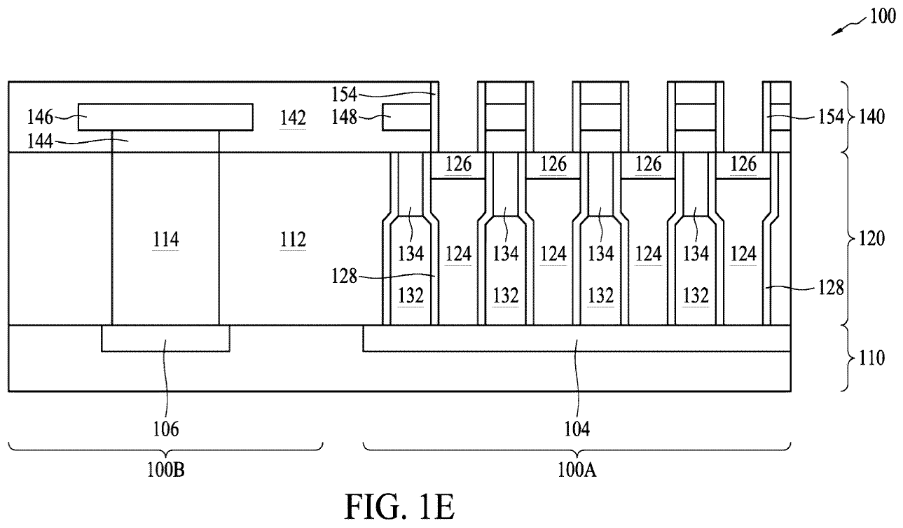

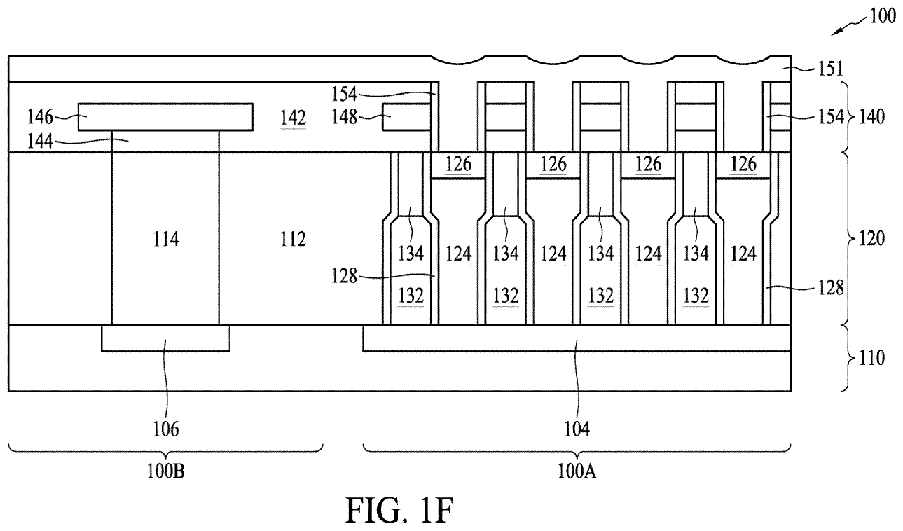

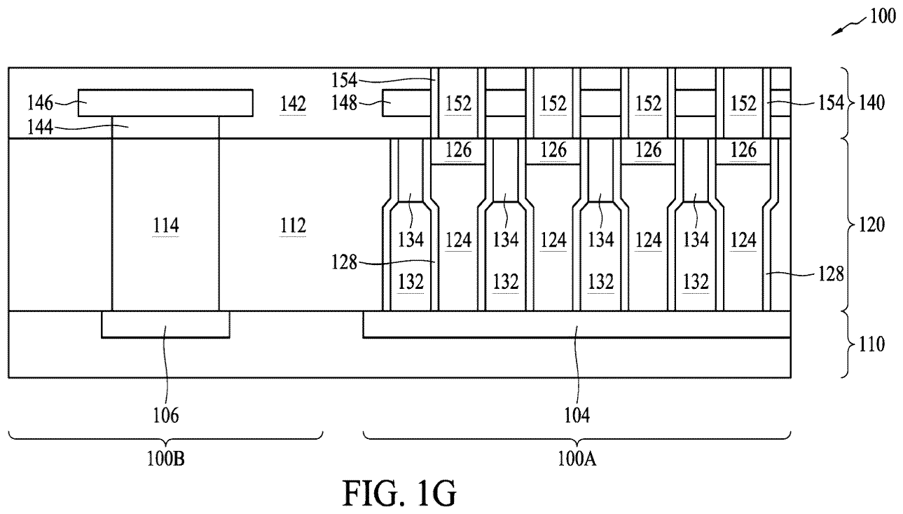

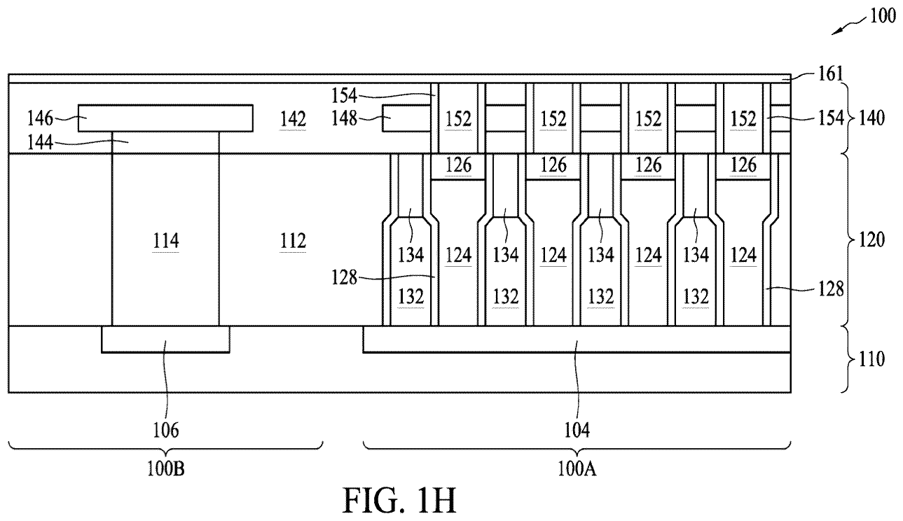

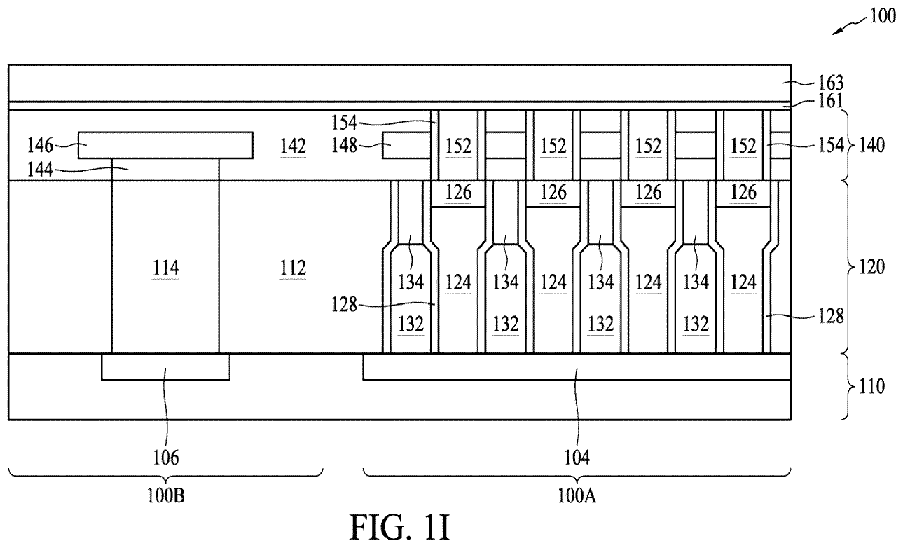

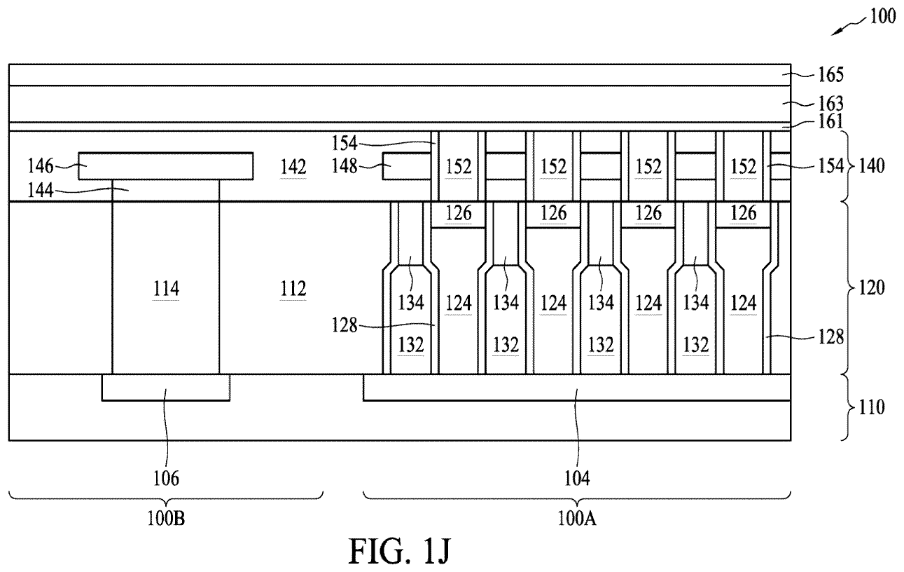

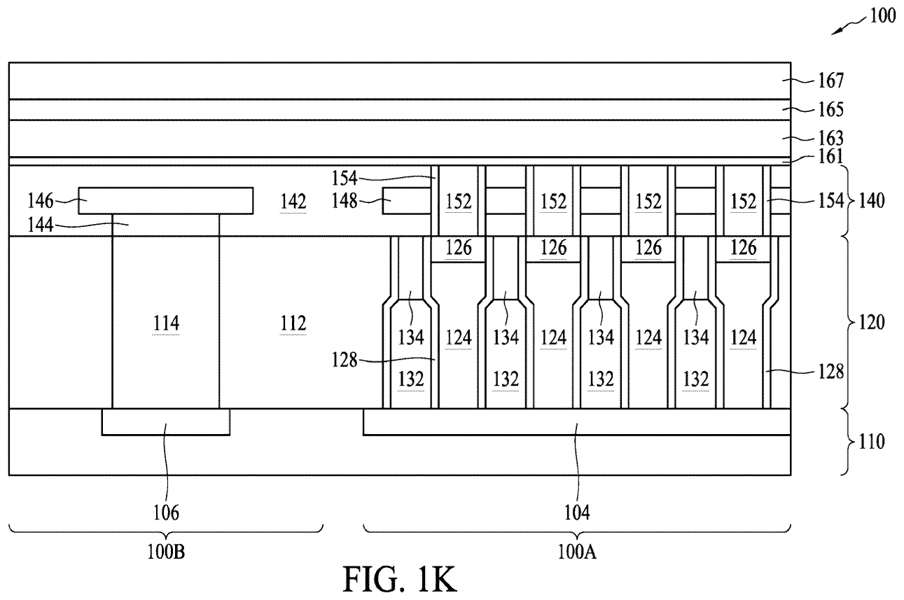

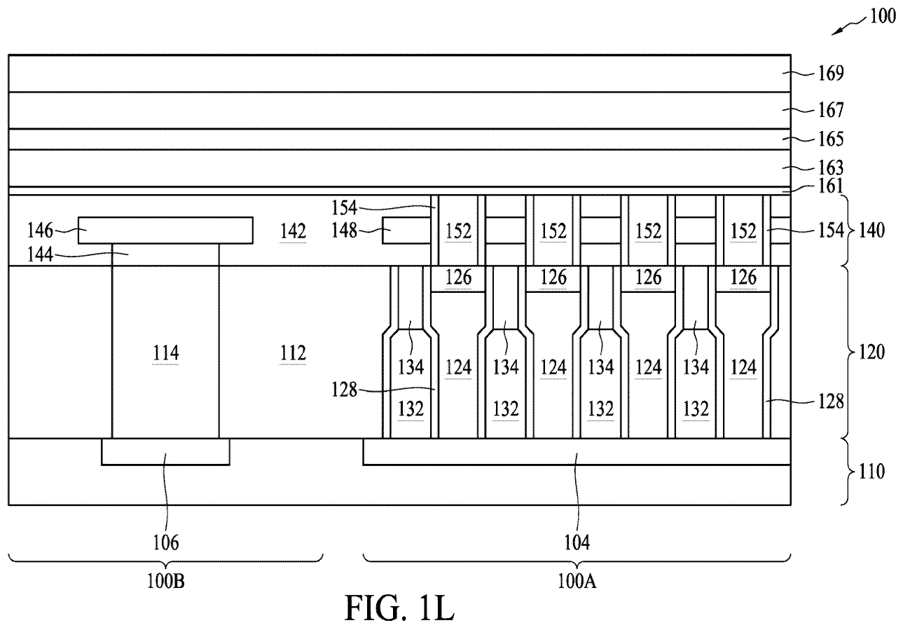

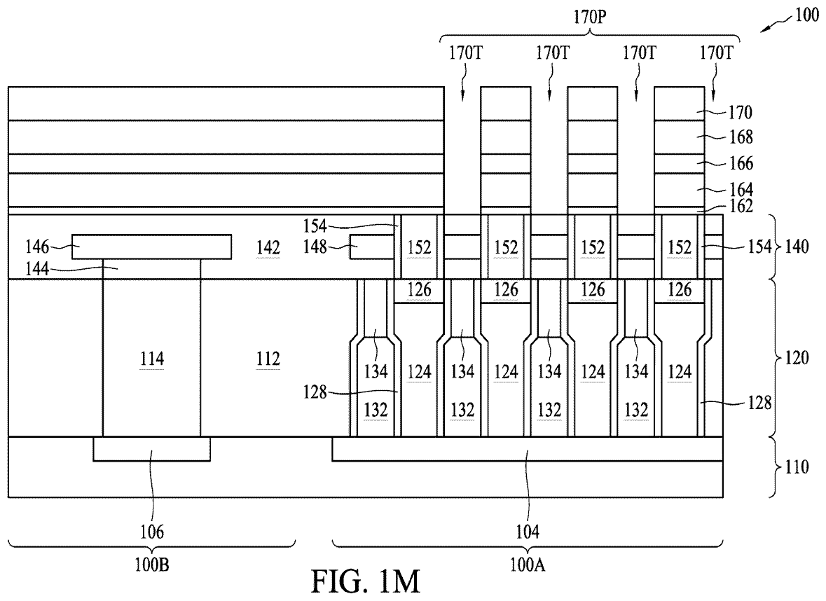

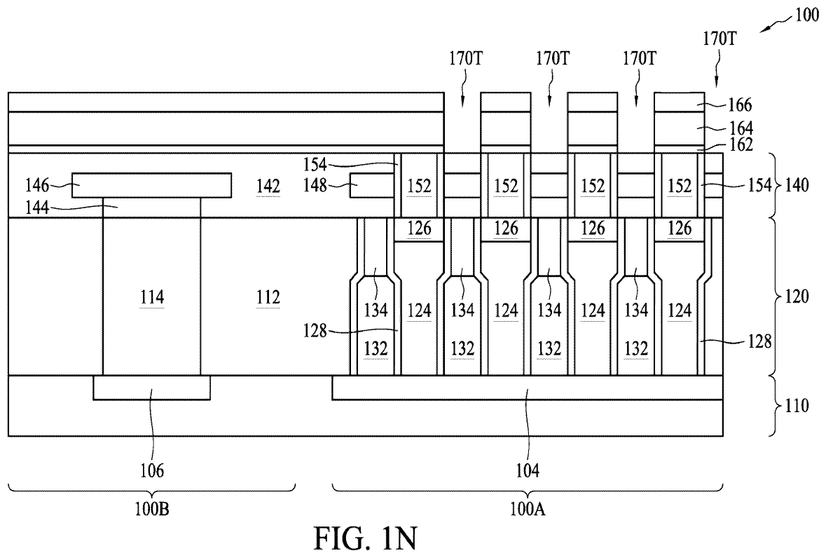

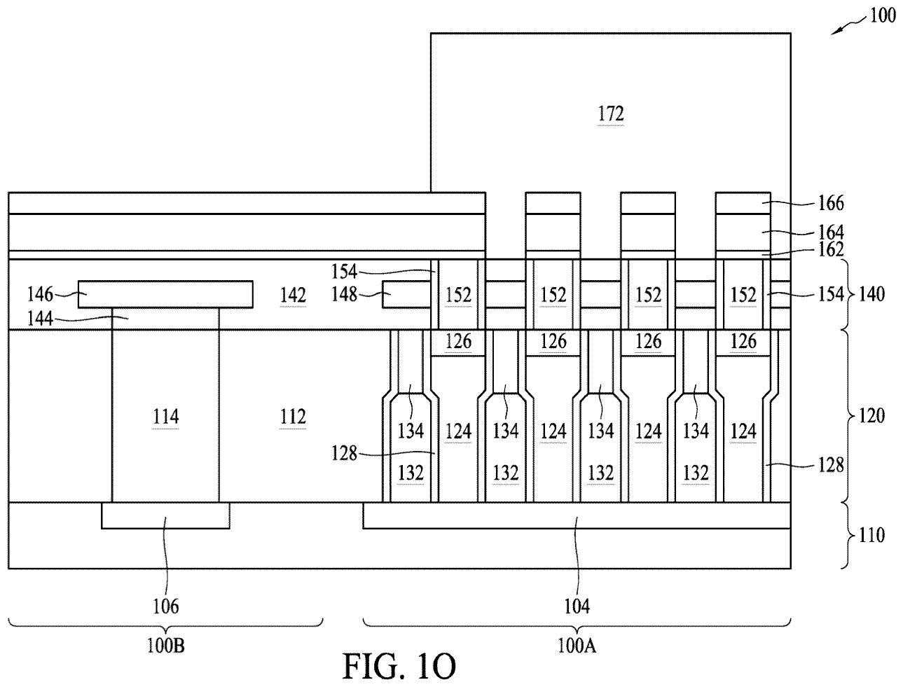

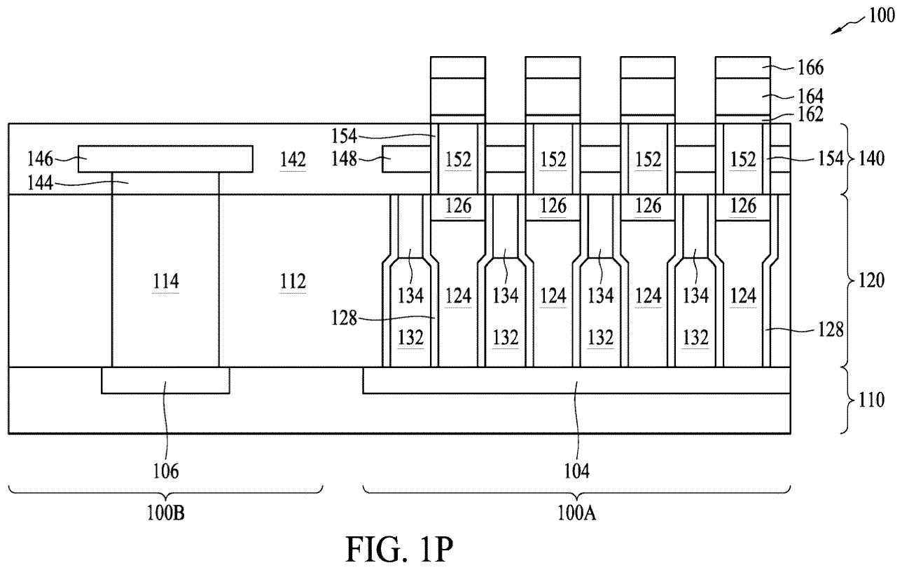

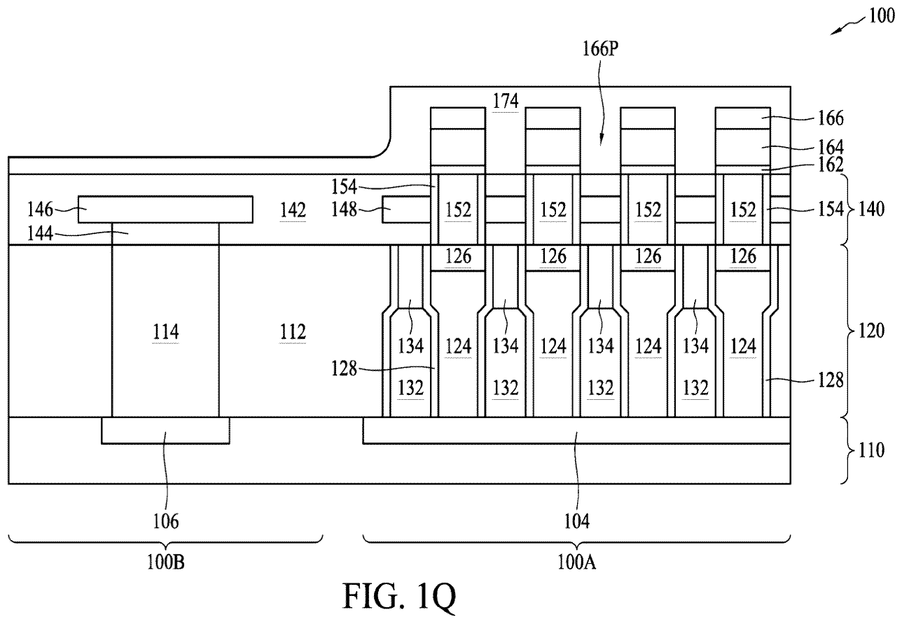

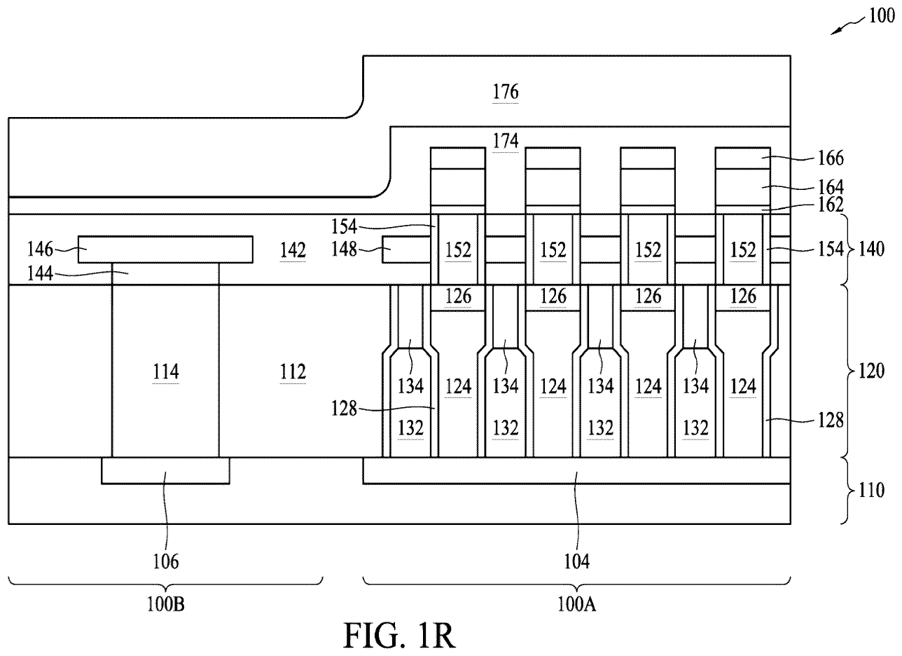

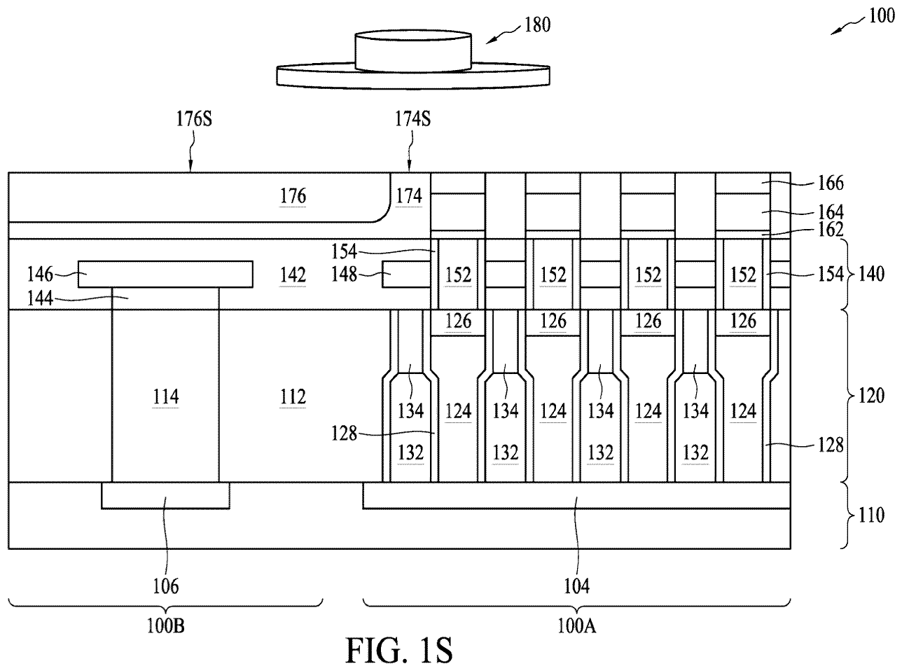

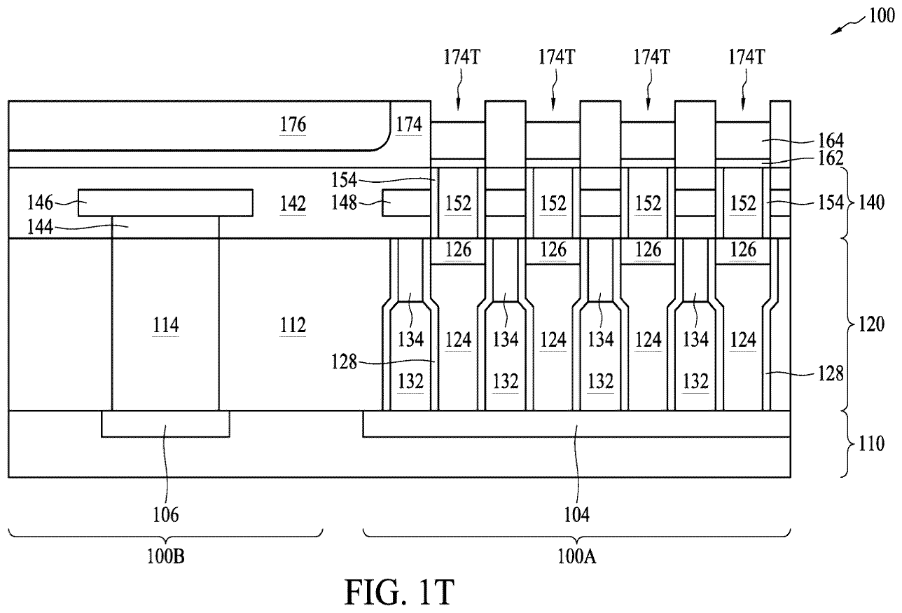

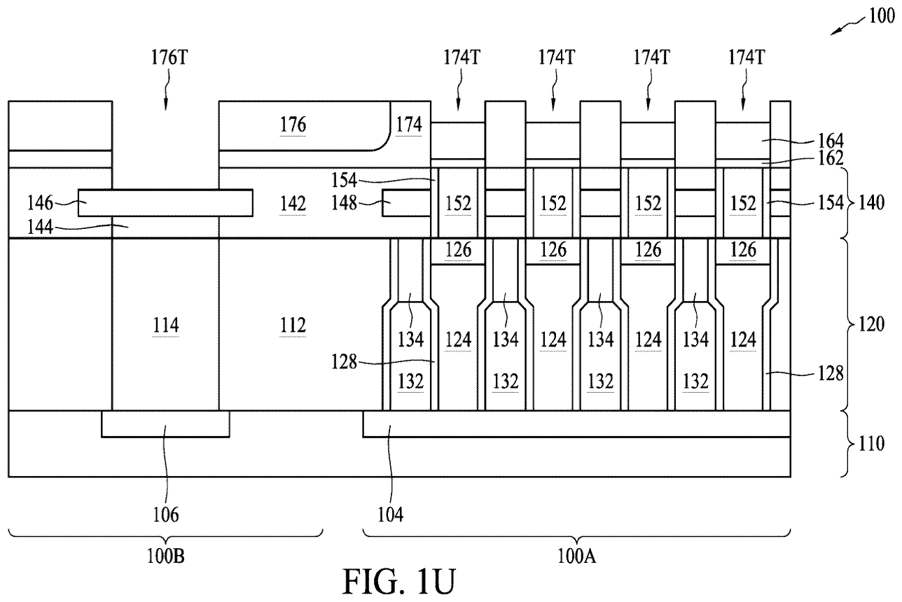

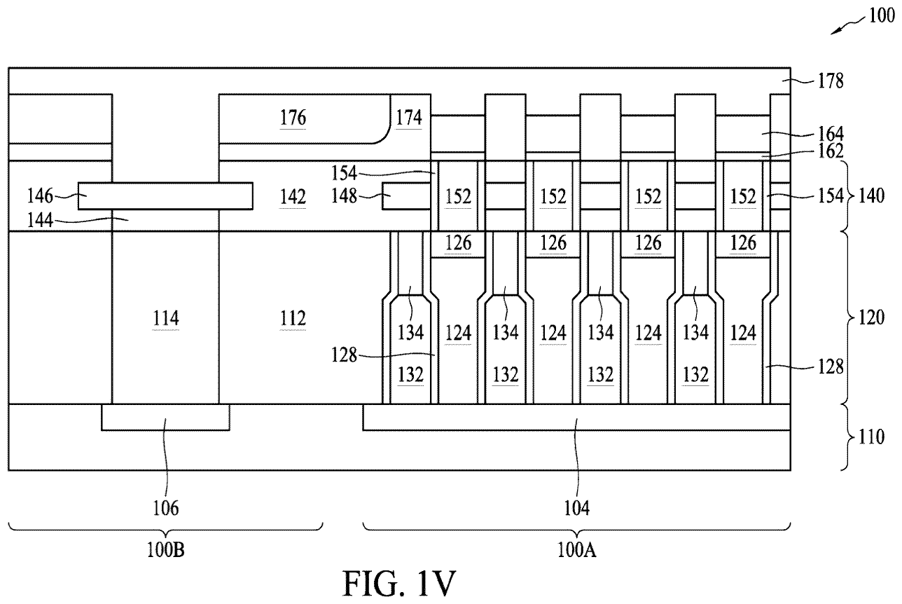

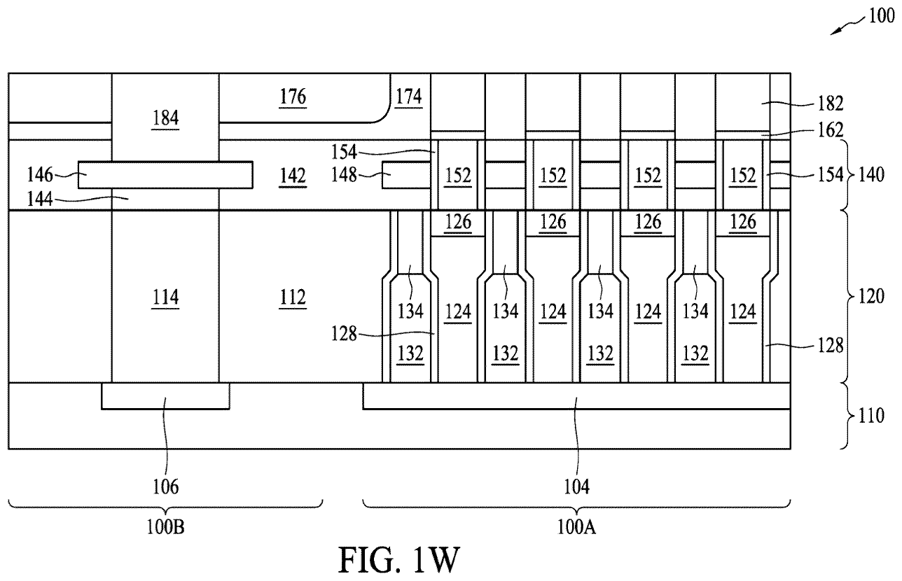

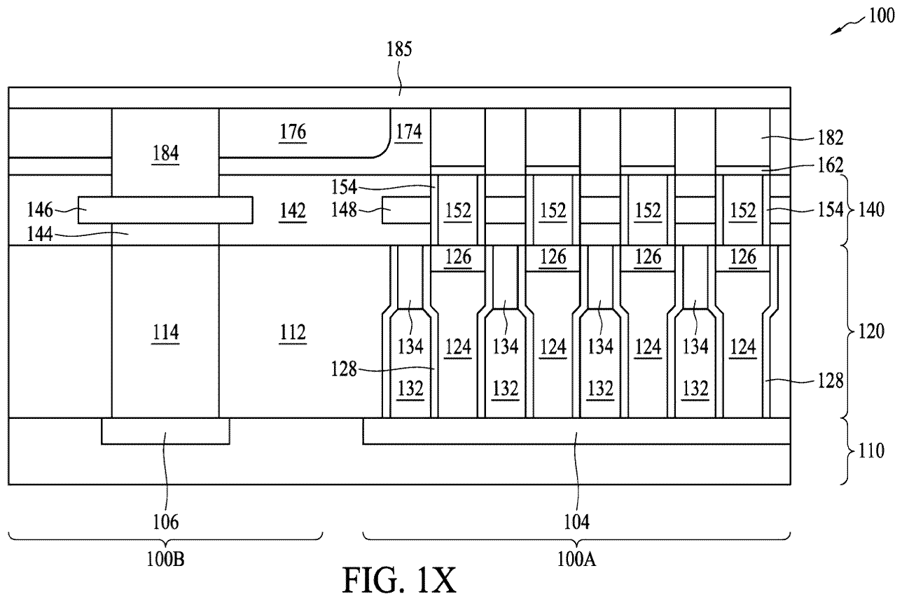

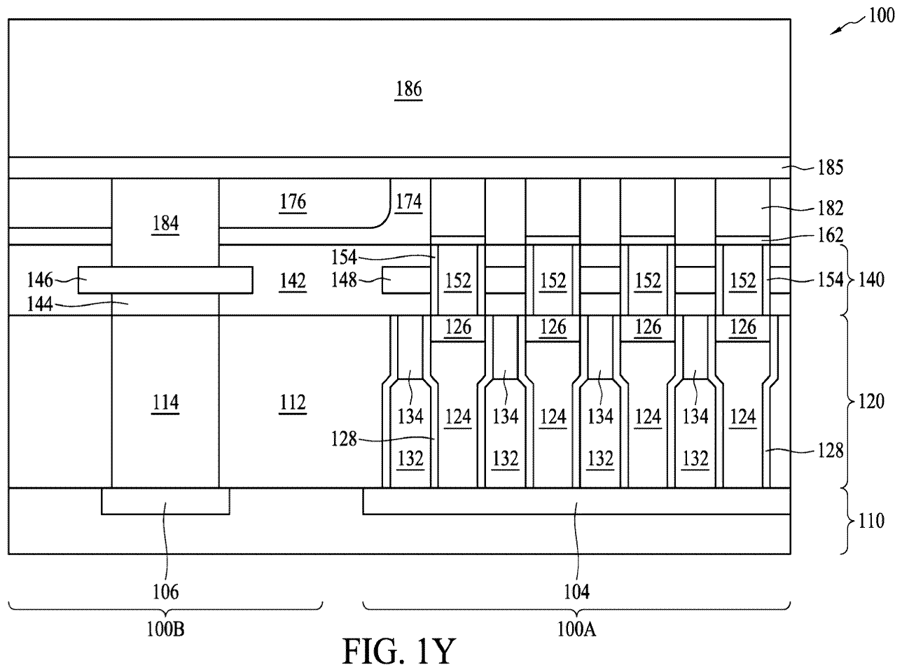

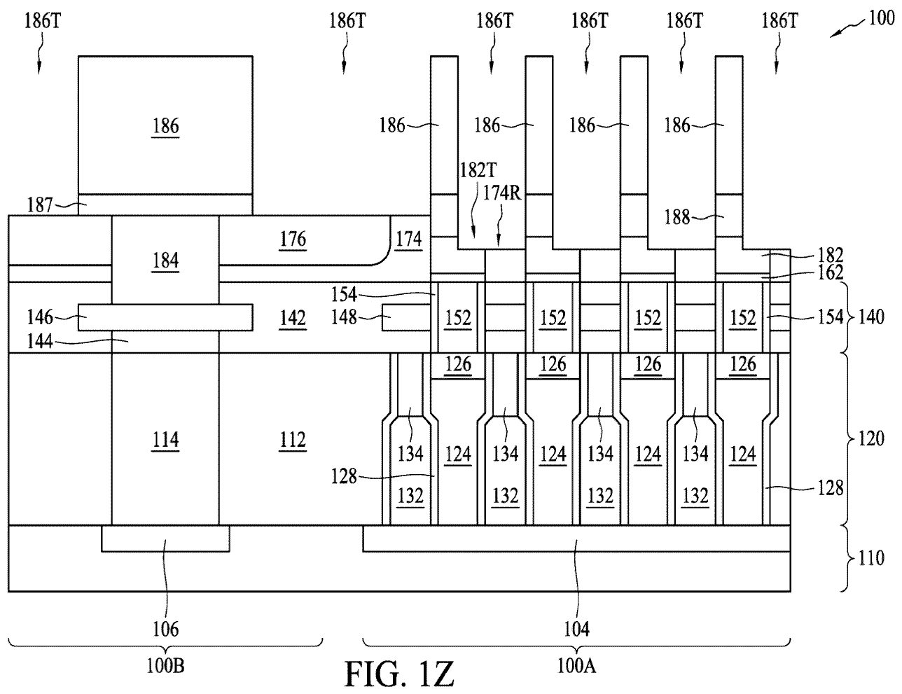

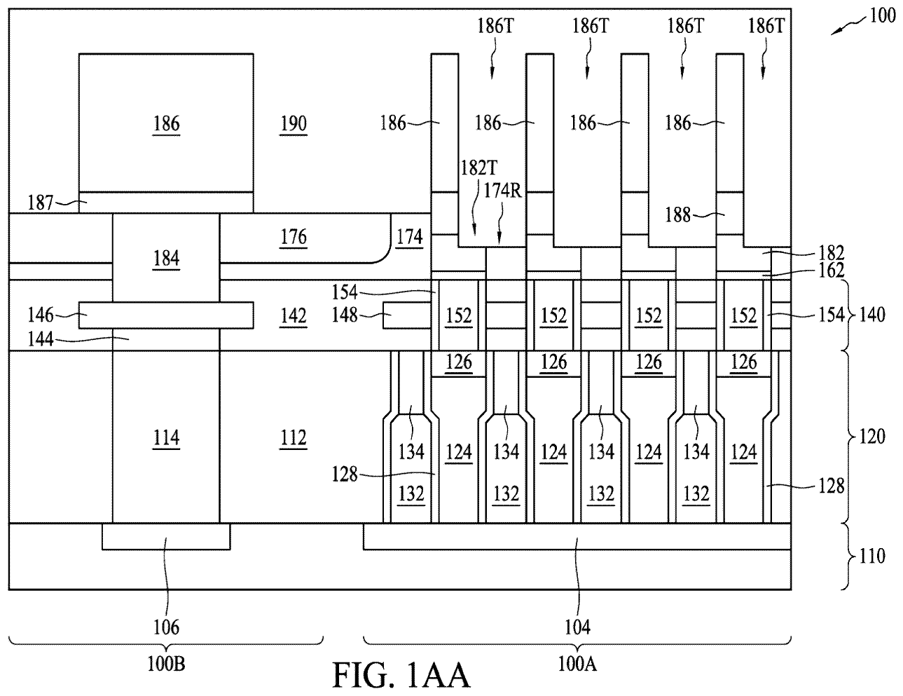

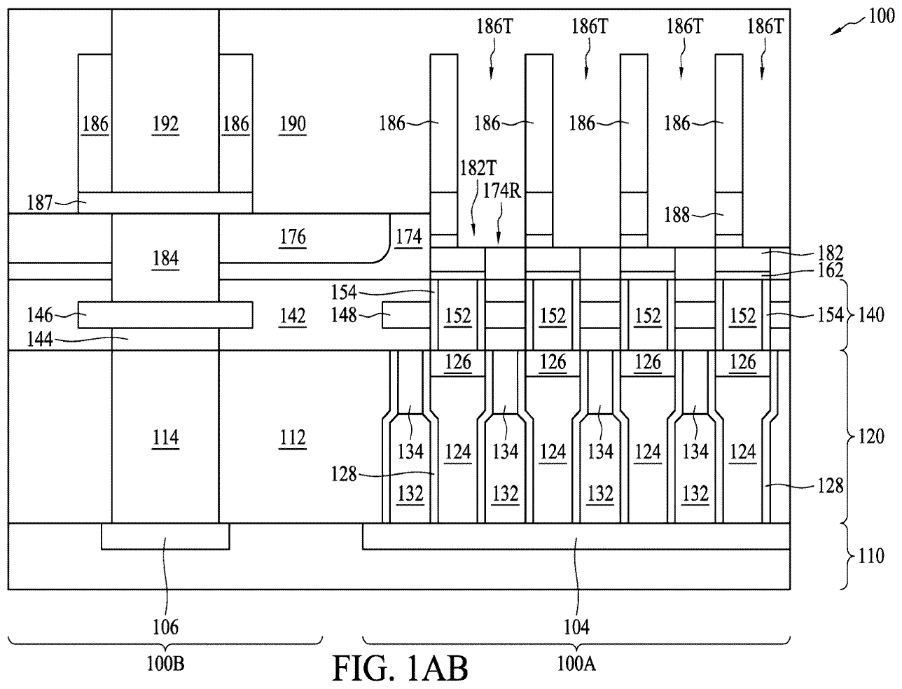

FIGS. 1A, 1B, 1C, 1D, 1E, 1F, 1G, 1H, 1I, 1J, 1K, 1L, 1M, 1N, 1O, 1P, 1Q, 1R, 1S, 1T, 1U, 1V, 1W, 1X, 1Y, 1Z, 1AA and 1AB are schematic cross-sectional views of intermediate stages of a method 10 for forming a semiconductor structure 100. It should be understood that additional steps can be provided before, during, and after the steps shown by FIGS. 1A to 1AB, and some steps described below can be replaced or eliminated in additional embodiments of the method 10. The steps may be performed independently, and the order of the steps may be interchanged.

Referring to FIG. 1A, in accordance with some embodiments, the semiconductor structure 100 is formed of a memory array, wherein the memory array includes dynamic random-access memory (DRAM) cells. A DRAM cell, i.e., a memory cell of the semiconductor structure 100, is generally formed of a data storage unit (memory unit) 124 configured to store data and a control unit configured to perform access operations on the data storage unit 124, such as a read operation and a write operation. The control unit is usually implemented by a transistor, e.g., a field-effect transistor (FET), such as a metal-oxide semiconductor (MOS) FET (MOSFET). In some embodiments of the present disclosure, the control unit of the DRAM can be formed of a planar FET. However, other types of FET, e.g., a fin-type FET (FinFET), a gate-all-around (GAA) FET, a nanosheet FET, a nanowire FET, or the like, are also within the contemplated scope of the present disclosure.

Referring to FIG. 1A, a substrate 110 is formed, received or provided. In some embodiments, the substrate 110 includes a semiconductor material such as bulk silicon. In some embodiments, the substrate 110 may include other semiconductor materials, such as silicon germanium, silicon carbide, gallium arsenide, or the like. In some embodiments, the substrate 110 is a p-type semiconductive substrate (acceptor type) or an n-type semiconductive substrate (donor type). Alternatively, the substrate 110 may include an elementary semiconductor, such as germanium; a compound semiconductor including gallium arsenic, gallium phosphide, indium phosphide, indium arsenide, or indium antimonide; an alloy semiconductor including SiGe, GaAsP, AlInAs, AlGaAs, GaInAs, GaInP, or GaInAsP; or a combination thereof. In addition, in accordance with some embodiments, the substrate 110 may include a portion of a semiconductor-on-insulator (SOI) substrate. In some embodiments, the substrate 110 may include a doped epitaxial layer, a gradient semiconductor layer, and/or a semiconductor layer overlaying another semiconductor layer of a different type, such as a silicon layer on a silicon germanium layer. In some embodiments, the substrate 110 is a hybrid substrate including first portions formed of a bulk silicon substrate and second portions formed of a SOI substrate.

In some embodiments, the semiconductor structure 100 includes a first region 100A and a second region 100B adjacent to the first region 100A. The first region 100A may be referred to as a memory array region, while the second region 100B may be referred to as a peripheral region. In some embodiments, the second region 100B is arranged in a periphery of the substrate 110 or laterally surrounds the first region 100A.

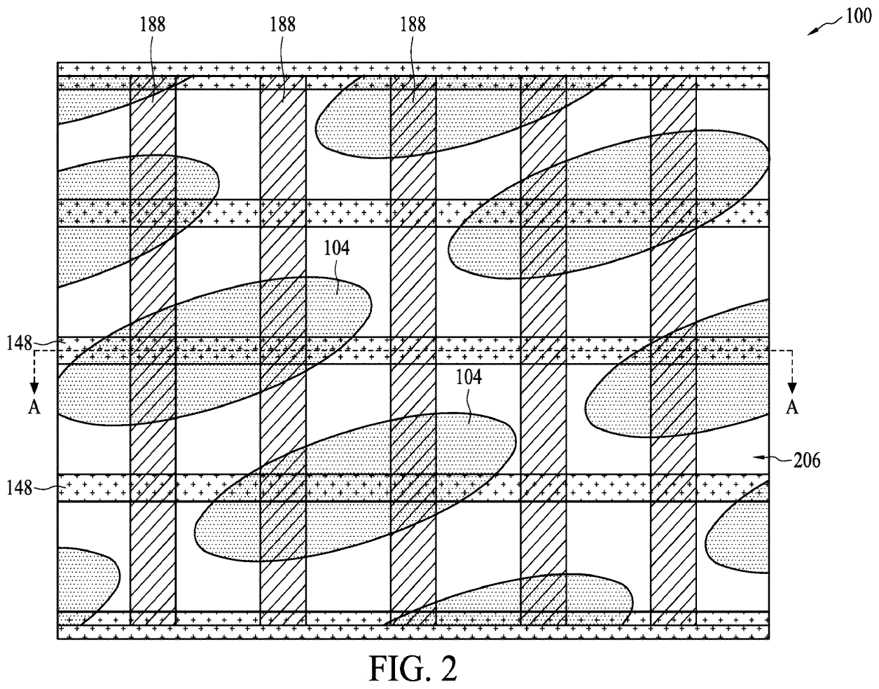

In some embodiments, an array of active regions 104 are formed in the substrate 110. The active regions 104 may be formed of doped regions with an n-type or p-type dopant. In some embodiments, the n-type dopant includes phosphorus (P), arsenic (As), antimony (Sb), or another suitable material. In some embodiments, the p-type dopant includes boron (B), indium (In), or another suitable material. A top view of the active regions 104 is shown in FIG. 2. Referring to FIG. 2, the active regions 104 may be separated by isolation regions 206, wherein the isolation regions 206 are formed of a dielectric material, e.g., silicon oxide, silicon nitride, silicon carbide, silicon oxynitride, high-k dielectric materials, or another suitable dielectric material. In some embodiments, the active regions 104 have an oval or elliptical shape from a top-view perspective. The active regions 104 may be formed to include source/drain regions therein for each control unit. In some embodiments, the isolation regions 206 define and electrically separate the active regions 104.

Referring to FIG. 1A, one or more semiconductor devices 106 are formed in the second region 100B of the substrate 110. The semiconductor device 106 may be utilized to perform auxiliary control functions for the memory cells of the semiconductor structure 100, e.g., data multiplexing, data demultiplexing, data encoding, data decoding, signal filtering, etc. The semiconductor device 106 may include one or more active devices, e.g., transistors or the like, or one or more passive devices, e.g., resistors, capacitors, inductors, diodes, fuses, or the like. The transistor is usually implemented by a field-effect transistor, such as a MOSFET. In some embodiments, the transistor 106 in the second region 100B can be formed of a planar FET. However, other types of FETs, e.g., a FinFET, a GAAFET, a nanosheet FET, a nanowire FET, or the like, are also within the contemplated scope of the present disclosure.

A first layer 120 is formed over the substrate 110. In some embodiments, a dielectric layer 112 is formed in the first layer 120. The dielectric layer 112 may include a dielectric material, e.g., silicon oxide, silicon nitride, silicon carbide, silicon oxynitride, high-k dielectric materials, or another suitable dielectric material. The first layer 120 may be a single layer structure or a multilayer structure formed of sublayers of various dielectric layers 112. The dielectric layer 112 may be formed through deposition, such as chemical vapor deposition (CVD), physical vapor deposition (PVD), atomic layer deposition (ALD), spin coating, or another suitable deposition method.

In some embodiments, a conductive via 114 is formed in the first layer 120 in the second region 100B and extends through the dielectric layer 112. The conductive via 114 may be electrically coupled to the underlying semiconductor device 106. The conductive via 114 is formed of a conductive material, e.g., copper, aluminum, tungsten, silver, gold, titanium, titanium nitride, tantalum, tantalum nitride, alloys thereof, or the like. In some embodiments, a formation process of the conductive via 114 comprises a patterning operation performed to form a trench (not separately shown) extending through the first layer 120 above the semiconductor device 106. The patterning operation may include photolithography and etching operations. The etching operations include a dry etch, a wet etch, a combination thereof (e.g., a reactive ion etch, RIE), or the like. Subsequently, a conductive material is deposited in the trench and over an upper surface of the dielectric layer 112 using, e.g., CVD, PVD, ALD, or the like. In some embodiments, a planarization operation, such as chemical mechanical polishing (CMP) or mechanical grinding, is performed to remove excess conductive material to thereby form the conductive via 114 and co-planarize an upper surface of the conductive via 114 with the upper surface of the dielectric layer 112.

In some embodiments, one or more dielectric layers 132 and 134 are formed in the first layer 120 of the first region 100A. The dielectric layers 132 and 134 may include a dielectric material, e.g., silicon oxide, silicon nitride, silicon carbide, silicon oxynitride, high-k dielectric materials, or another suitable dielectric material. The formation of the dielectric layers 132 and 134 may be similar to the formation of the dielectric layer 112. In some embodiments, the first layer 120 includes a multilayer structure formed of the dielectric layers 132 and 134, instead of the single-layer structure 112, wherein the first layer 120 extends across the first region 100A and the second region 100B.

An array of data storage units 124 is formed in the first layer 120, e.g., in the dielectric layers 132 and 134, of the first region 100A. The array of data storage units 124 may be electrically coupled to the underlying active regions 104. Each of the data storage units 124 is formed of a capacitor, which can be a deep-trench type capacitor or a metal-insulator-metal (MIM) type capacitor. In some embodiments, each data storage unit 124 may comprise two electrode plates and an insulating film between the two electrode plates, where only one electrode plate (also labeled with the numeral 124) of each data storage unit 124 is illustrated in FIG. 1A. The electrode plates of the data storage unit 124 are formed of a conductive material, e.g., copper, aluminum, tungsten, silver, gold, titanium, titanium nitride, tantalum, tantalum nitride, alloys thereof, or the like, using CVD, PVD, ALD, or another suitable deposition method. The insulating film between the electrode plates may be formed of dielectric materials, such as silicon oxide, silicon nitride, high-k dielectric materials, or the like.

In some embodiments, the semiconductor structure 100 may further include a conductive layer 126 arranged on an upper side of each data storage unit 124. The conductive layer 126 may include a conductive oxide layer formed of a conductive oxide material, e.g., indium tin oxide (ITO), indium tungsten oxide (IWO), or another conductive oxide material. In some embodiments, the conductive layer 126 includes transparent conductive oxide. The conductive layer 126 may be used to electrically couple the electrode plate of the data storage unit 124 to overlying structures. The conductive layer 126 may be formed by CVD, PVD, ALD, or another suitable deposition method.

In some embodiments, each of the data storage units 124 includes a liner 128 formed on sidewalls of the electrode plate. The liner 128 may include a dielectric material, e.g., silicon oxide, silicon nitride, silicon carbide, silicon oxynitride, high-k dielectric materials, or another suitable dielectric material. In some embodiments, the liner 128 is deposited in a conformal manner along sidewalls of the electrode plates with a substantially uniform thickness. In some embodiments, upper surfaces of the dielectric layer 112, the conductive via 114, the dielectric layer 134, the liner 128, and the conductive layer 126 are coplanar.

In some embodiments, the electrode plate labeled with the numeral 124 includes two segments from a cross-sectional view. An upper segment of the electrode plate 124 is connected to a lower segment of the electrode plate 124, wherein the upper segment may have a width greater than a width of the lower segment.

Referring to FIG. 1B, a second layer 140 is formed over the first layer 120. The second layer 140 includes a dielectric layer 142 formed across the first region 100A and the second region 100B. The dielectric layer 142 may include a dielectric material, e.g., silicon oxide, silicon nitride, silicon carbide, silicon oxynitride, high-k dielectric materials, or another suitable dielectric material. The dielectric layer 142 may be a single layer structure or a multilayer structure formed of sublayers of various dielectric materials, e.g., by CVD, PVD, ALD, or another suitable deposition method.

A word line 148 is formed in the second layer 140 in the first region 100A. The word line 148 may be surrounded and electrically insulated by the dielectric layer 142. The word line 148 may include a conductive material, such as tungsten; however, other suitable conductive materials, e.g., copper, aluminum, silver, gold, titanium, titanium nitride, tantalum, tantalum nitride, alloys thereof, and the like, are also within the contemplated scope of the present disclosure.

A conductive pad 144 and a conductive line 146 are formed in the second layer 140 in the second region 100B. The conductive pad 144 may electrically couple the conductive via 114 to the conductive line 146. The conductive line 146 and the word line 148 are formed at a same elevation of the second layer 140 during a single deposition operation. The conductive pad 144 and the conductive line 146 may include a conductive material, such as tungsten; however, other suitable conductive materials, e.g., copper, aluminum, silver, gold, titanium, titanium nitride, tantalum, tantalum nitride, alloys thereof, and the like, are also within the contemplated scope of the present disclosure.

In some embodiments, in accordance with a process for forming the dielectric layer 142, a first dielectric sublayer (not separately shown) of the dielectric layer 142 is deposited over an upper surface of the first layer 120. A patterning operation is performed to form recesses on an upper surface of the first dielectric sublayer. A conductive material of the conductive pad 144 is deposited in the recesses of the first dielectric sublayer. In some embodiments, a planarization operation may be used to remove excess material of the conductive material from the upper surface of the first dielectric sublayer and thereby form the conductive pad 144. Subsequently, a second dielectric sublayer (not separately shown) is then deposited over the first dielectric sublayer and the conductive pad 144, e.g., by a suitable deposition method. A patterning operation is performed to form recesses on an upper surface of the second dielectric sublayer. A conductive material of the word line 148 and the conductive line 146 is deposited in the recesses of the first dielectric sublayer. In some embodiments, a planarization operation may be used to remove excess material of the conductive material from the upper surface of the second dielectric sublayer and thereby form the word line 148 and the conductive line 146. A third dielectric sublayer (not separately shown) is then deposited over the second dielectric sublayer, the word line 148, and the conductive line 146, e.g., by a suitable deposition method.

Referring to FIG. 1C, the second layer 140 is patterned to form a plurality of trenches 142T in the first region 100A, wherein the plurality of trenches 142T extend through the word line 148 and align with corresponding data storage units 124. Upper surfaces of the corresponding conductive layers 126 are exposed accordingly. The trenches 142T may have a diameter or width less than a width of the word line 148 such that portions of the trenches 142T at a same level as the word line 148 are within a circumference of the word line 148. In some embodiments, the trenches 142T are formed by photolithography and etching operations. The etching operation may be performed by a dry etch, a wet etch, an RIE, or the like.

Referring to FIG. 1D, an insulating film 153 is deposited on sidewalls and bottoms of the trenches 142T. The insulating film 153 may further be deposited over surfaces of the dielectric layer 142. The insulating film 153 may include a dielectric material, such as silicon oxide; however, other dielectric materials, e.g., silicon nitride, silicon carbide, silicon oxynitride, high-k dielectric materials, and other suitable dielectric materials, are also within the contemplated scope of the present disclosure. The insulating film 153 may be deposited to a substantially uniform thickness, i.e., in a conformal manner, using CVD, ALD, or another suitable deposition method.

FIG. 1E illustrates an etching operation on the insulating film 153. As a result of the etching operation, insulating films 154 are formed on the sidewalls of the individual trenches 142T. The etching operation may be performed using an anisotropic etching operation to etch horizontal portions of the insulating film 153 at the bottoms of the trenches 142T and on an upper surface of the dielectric layer 142. The etching operation may include a dry etch, a wet etch, an RIE, or the like.

Referring to FIG. 1F, a conductive oxide layer 151 is deposited in the trenches 142T between the insulating films 154. The conductive oxide layer 151 may also be deposited over the upper surface of the dielectric layer 142. In some embodiments, the conductive oxide layer 151 includes transparent conductive oxide. In some embodiments, the conductive oxide layer 151 includes indium gallium zinc oxide (IGZO) or another suitable conductive oxide material.

Referring to FIG. 1G, a planarization operation is performed to remove excess materials of the conductive oxide layer 151 to form individual channel layers 152. The planarization operation may also cause upper surfaces of the channel layers 152 to be level with the upper surface of the dielectric layer 142. The planarization operation may be performed using CMP, mechanical grinding, or another suitable polishing operation. In some embodiments, the channel layers 152 serve as the channels of respective control units for allowing an access current to flow through. The word line 148 is electrically insulated from the channel layers 152 through the intervening insulating films 154, and the word line 148 is configured to be biased at a suitable voltage to control movement of carriers in the channel layers 152 during a read or write operation. In some embodiments, each channel layer 152 extends through the word line 148 and is laterally surrounded by the word line 148.

Referring to FIG. 1H, a conductive material 161 is deposited over an upper surface of the second layer 140. In some embodiments, the conductive material 161 extends across the first region 100A and the second region 100B. The conductive material 161 may cover each of the channel layers 152. The conductive material 161 (or a patterned conductive layer 162 formed therefrom; see FIG. 1M) may be used to electrically couple the channel layers 152 to overlying structures through a patterning operation, which is described below. In some embodiments, the conductive material 161 includes a conductive oxide material, e.g., indium tin oxide (ITO), indium tungsten oxide (IWO), or other conductive oxide material. In some embodiments, the conductive material 161 includes transparent conductive oxide. The conductive material 161 has a material similar to that of the conductive layer 126. The conductive material 161 is formed by CVD, PVD, ALD, or another suitable deposition method. In some embodiments, each of the channel layer 152, the conductive layer 126 and the conductive material 161 (or the patterned conductive layer 162) is formed of a conductive oxide material. In some embodiments, the channel layer 152 includes a conductive oxide material different from a material of the conductive layer 126 or the conductive material 161 (or the patterned conductive layer 162).

Referring to FIG. 1I, another conductive material 163 is deposited over an upper surface of the conductive material 161. In some embodiments, the conductive material 163 extends across the first region 100A and the second region 100B. In some embodiments, the conductive material 163 includes a metallic material, e.g., tungsten; however, other suitable conductive materials, e.g., copper, aluminum, silver, gold, titanium, titanium nitride, tantalum, tantalum nitride, alloys thereof, and the like, are also within the contemplated scope of the present disclosure. The conductive material 163 may be formed by CVD, PVD, ALD, or another suitable deposition method. In some embodiments, the conductive material 163 includes a metallic material similar to that of the word line 148.

Referring to FIG. 1J, an etch stop layer 165 is deposited over an upper surface of the conductive material 163. In some embodiments, the etch stop layer 165 extends across the first region 100A and the second region 100B. In some embodiments, the etch stop layer 165 includes silicon nitride, silicon carbide, carbon, silicon oxynitride, high-k dielectric materials, or another suitable dielectric material. The etch stop layer 165 may serve as a hard mask that will be patterned during a patterning operation to form a patterned array of conductive pads from the conductive materials 161 and 163. The etch stop layer 165 may be formed by CVD, PVD, ALD, or another suitable deposition method.

Referring to FIG. 1K, a hard mask layer 167 is deposited over the etch stop layer 165. In some embodiments, the hard mask layer 167 extends across the first region 100A and the second region 100B. In some embodiments, the hard mask layer 167 includes a material different from a material of the etch stop layer 165, e.g., the hard mask layer 167 is formed of carbon or another suitable material, such as silicon oxynitride or a high-k dielectric material. The hard mask layer 167 may serve as a mask layer that will be patterned during a patterning operation to form a pattern and transfer such pattern to the etch stop layer 165. The hard mask layer 167 may be formed by CVD, PVD, ALD, or another suitable deposition method.

Referring to FIG. 1L, a photoresist or a mask layer 169 is deposited over an upper surface of the hard mask layer 167. In some embodiments, the photoresist 169 extends across the first region 100A and the second region 100B. In some embodiments, the photoresist 169 can be etched into a specific pattern during a photolithography operation to facilitate the etching operation of the underlying layers. In some embodiments, the photoresist 169 is formed of a multilayer structure and includes an under layer serving as an antireflection coating. The under layer may include a polymer-based material. In some embodiments, the photoresist 169 further includes a dielectric antireflection coating (DARC) deposited over the under layer. In some embodiments, the DARC includes a dielectric material, e.g., silicon oxide, silicon nitride, silicon oxynitride, or another suitable dielectric material. In some embodiments, the under layer and the DARC are formed by CVD, PVD, ALD, spin coating, or another suitable deposition method.

Referring to FIG. 1M, one or more patterning operations are performed sequentially to pattern the stack of the hard mask layer 167, the etch stop layer 165, the conductive material 163 and the conductive material 161. In some embodiments, the photoresist 169 is etched into a patterned photoresist or a patterned mask layer 170, wherein the patterned photoresist 170 includes a pattern 170P corresponding to a pattern of conductive pads. The hard mask layer 167 is patterned into a patterned hard mask layer 168 by a first etching operation using the patterned photoresist 169 as an etching mask. The pattern 170P is thus transferred from the patterned photoresist 170 to the patterned hard mask layer 168. Subsequently, the etch stop layer 165 is patterned into a patterned etch stop layer 166 by a second etching operation using the patterned hard mask layer 166 as an etching mask. The pattern 170P is thus transferred to the patterned etch stop layer 166. The patterned etch stop layer 166 can be used in a third etching operation to pattern the conductive material 163 and the conductive material 161 into an array of conductive pads 164 and an array of conductive layers 162. The pattern 170P is thus transferred to the conductive pads 164 and the conductive layers 162. In some embodiments, the conductive pads 164 are landing pads to electrically couple to bit lines 188 (described below) of the semiconductor structure 100.

In some embodiments, each of the first etching operation, the second etching operation and the third etching operation may be performed by a dry etch, a wet etch, an RIE, or the like. The first etching operation, the second etching operation, and the third etching operation may be performed in a single operation or performed separately. Similarly, the etching of the conductive material 161 and the conductive material 163 can be performed by subsequent etching operations or during a single etching operation. In some embodiments, through the one or more patterning operations, a portion of the upper surface of the dielectric layer 142 between the conductive layers 162 is exposed accordingly. In some embodiments, an etchant used to etch the conductive material 163 or 161 is selective to the conductive material 163 or 161 with respect to a material of the etch stop layer 165 or the dielectric layer 142 such that the etching can stop on the dielectric layer 142.

Referring to FIG. 1N, the patterned photoresist 170 is removed or stripped after the patterning of the conductive pads 161 and 163 is completed. In some embodiments, the patterned hard mask layer 168 is also removed or stripped. The removal of the patterned photoresist 170 and the patterned hard mask layer 168 may include a dry etch, a wet etch, an RIE, an ashing operation, or the like. As a result, an upper surface of the patterned etch stop layer 166 is exposed.

Referring to FIG. 1O, a photoresist 172 is provided to cover the first region 100A. The second region 100B is exposed accordingly. The photoresist 172 may be deposited over the first region 100A by CVD, PVD, spin coating, or another suitable deposition method. In some embodiments, the photoresist 172 includes a single-layer structure of a multilayer structure.

Referring to FIG. 1P, portions of the patterned etch stop layer 166, the conductive material 163 and the conductive material 161 left in the second region 100B are removed. The removal operation may be performed by an etching operation using the photoresist 172 as an etching mask. The etching operation may include a dry etch, a wet etch, an RIE or the like. As a result, the upper surface of the dielectric layer 142 of the second region 100B is exposed. In some embodiments, the photoresist 172 is stripped or removed after the etching operation. The etch stop layer 166 and the dielectric layer 142 in the first region 100A are exposed again.

FIG. 1Q shows a formation of a dielectric layer 174 over the dielectric layer 142 and the conductive pads 164. The dielectric layer 174 may extend across the first region 100A and the second region 100B. In some embodiments, the dielectric layer 174 covers the patterned etch stop layer 166 and fills spaces 166P between the adjacent conductive layers 162, between the adjacent conductive pads 164, and between adjacent portions of the patterned etch stop layer 166. The deposited dielectric layer 174 covers an entirety of the patterned etch stop layer 166 in the first region 100A and the upper surface of the dielectric layer 142 in the second region 100B. The dielectric layer 174 also contacts the upper surface of the dielectric layer 142 in the first region 100A. The dielectric layer 174 may include a dielectric material, e.g., silicon oxide, different from a material of the patterned etch stop layer 166. In some embodiments, the dielectric layer 174 is formed by ALD to improve gap-filling performance in the spaces 166P; however, other deposition methods such as PVD or CVD may also be used.

Referring to FIG. 1R, another dielectric layer 176 is deposited over the dielectric layer 174. The dielectric layer 176 may extend across the first region 100A and the second region 100B. In some embodiments, the dielectric layer 176 covers the dielectric layer 174. The dielectric layer 176 may include a dielectric material, e.g., silicon oxide, different from a material of the patterned etch stop layer 166. The dielectric layer 176 may have a material, e.g., silicon oxide, similar to a material of dielectric layer 174. The dielectric layer 176 may be formed by CVD, PVD, ALD, spin coating, or another suitable deposition method.

Referring to FIG. 1S, a planarization operation is performed by a tool 180. In some embodiments, the planarization operation includes CMP. As a result, a portion of the dielectric layer 176 and a portion of the dielectric layer 174 are thinned or removed. In some embodiments, the tool 180 includes a polishing pad configured to reduce a thickness of the dielectric layer 174 or a thickness of the dielectric layer 176. Since the material of the etch stop layer 166 is different from, e.g., harder than, the materials of the dielectric layers 174 and 176, the planarization operation may stop at the etch stop layer 166 during the thinning of the dielectric layers 174 and 176. Therefore, an upper surface of each patterned etch stop layer 166 is exposed during the planarization operation. The upper surface of the etch stop layer 166 may be substantially level with the upper surface 174S of the dielectric layer 174 and the upper surface 176S of the dielectric layer 176 with a surface roughness caused by the polishing pad. In some embodiments, a slight thickness of the etch stop layer 166 may be consumed during the planarization operation, but the etch stop layer 166 is not be removed during the planarization operation; accordingly, the underlying conductive pads 164 can be effectively protected, i.e., the upper surfaces of the conductive pads 164 are covered during the planarization operation.

Referring to FIG. 1T, the etch stop layer 166 is removed from the upper surface of the conductive pads 164. The removal of the etch stop layer 166 may include a dry etch, a wet etch, an RIE, or the like. The upper surface of the conductive pads 164 are exposed accordingly. Etchants of the etching operation may be selective to the etch stop layer 166 with respect to the dielectric layers 174, 176 and the conductive pads 164 such that the dielectric layers 174, 176 and the conductive pads 164 are kept substantially intact during the etching of the etch stop layer 166. Therefore, trenches 174T are formed within the dielectric layer 174 over the conductive pads 164.

Referring to FIG. 1U, a via 176T is formed in the second region 100B over the conductive line 146. The via 176T extends through the dielectric layer 176, the dielectric layer 174, and the dielectric layer 142, and exposes the underlying conductive line 146. The via 176T may be formed by photolithography and etching operations. The etching operation may include a dry etch, a wet etch, an RIE or the like. The etching operation may include an anisotropic etch.

Referring to FIG. 1V, a conductive material 178 is deposited over the dielectric layer 174 and the dielectric layer 176 and fills the trenches 174T and the via 176T. In some embodiments, the conductive material 178 extends over the surfaces of the dielectric layers 174 and 176. The conductive material 178 may be same as the material of the conductive pads 164, e.g., tungsten, or other conductive material such as copper, aluminum, silver, gold, titanium, titanium nitride, tantalum, tantalum nitride, alloys thereof, or the like. The deposition of the conductive material 178 may be performed by CVD for facilitating gap-filling performance of the conductive material 178 in the trenches 174T and 176T.

Referring to FIG. 1W, excess portions of the conductive material 178 are removed by a planarization operation, e.g., CMP or mechanical grinding. The upper surfaces of the dielectric layers 174 and 176 are exposed again during the planarization operation. The heights of the original conductive pads 164 are increased to form conductive pads 182, wherein the conductive pads 182 include upper surfaces level with the upper surfaces of the dielectric layer 174 or the dielectric layer 176. In addition, in accordance with some embodiments, the planarization operation forms a conductive via 184 in the second region 100B, wherein an upper surface of the conductive via 184 is level with the upper surface of the dielectric layer 174 or the upper surface of the dielectric layer 176. The conductive via 184 may be electrically coupled to the underlying conductive line 146.

Referring to FIG. 1X, a conductive layer 185 is formed over the dielectric layers 174 and 176, the conductive pads 182, and the conductive via 184. The conductive layer 185 may have materials same as those of the conductive pads 164 or the conductive material 178, e.g., tungsten, or another conductive material, such as copper, aluminum, silver, gold, titanium, titanium nitride, tantalum, tantalum nitride, alloys thereof, or the like. A deposition process, such as a PVD process using a material of the conductive layer 185, may be performed to improve electrical or mechanical properties of the conductive layer 185. In some embodiments, a planarization operation, e.g., CMP, is performed to planarize an upper surface of the conductive layer 185.

Referring to FIG. 1Y, a dielectric layer 186 is deposited over the conductive layer 185. The dielectric layer 186 may include a dielectric material, e.g., silicon oxide, silicon nitride, silicon carbide, silicon oxynitride, high-k dielectric materials, or another suitable dielectric material. The dielectric layer 186 may be a single layer structure or a multilayer structure formed of sublayers of various dielectric materials. The dielectric layer 186 may be formed by deposition, such as CVD, PVD, ALD, spin coating, or another suitable deposition method.

Referring to FIG. 1Z, a patterning operation is performed on the dielectric layer 185 to form trenches 186T through the dielectric layer 186. The trenches 186T extend into the dielectric layer 174, the conductive layer 185 and the conductive pads 182. A conductive pad 187 is thus formed over the conductive via 184. In some embodiments, the conductive pad 187 has a width or a surface area greater than that of the conductive via 184. In some embodiments, the patterning operation removes portions of the conductive pads 182 to form bit lines 188 over the conductive pads 182. A portion 182T of the conductive pad 182 and a portion 174R of the dielectric layer 174 are etched through the patterning operation to form the bit lines 188 and the conductive pads 182. In some embodiments, remaining portions of the dielectric layer 174 laterally surround the conductive pads 182.

Although not shown, it should be understood that the conductive pads 182 are formed over the channel layers 152 of the corresponding storage units 124, while each of the bit lines 188 is formed as a conductive line extending in a direction toward the viewer of FIG. 1Z to be electrically coupled to the individual channel layers 152. In addition, each portion of the dielectric layer 174 between adjacent conductive pads 182 may be lower than the upper surface of the dielectric layer 176 from a cross-sectional view. An interface between the dielectric layer 174 and the conductive pads 182 may be exposed. The trench 186T may be formed by photolithography and etching operations. The etching operation may include a dry etch, a wet etch, an RIE, or the like. The etching operation may comprise an anisotropic etch.

Referring to FIG. 1AA, a dielectric layer 190 is deposited over the dielectric layers 174, 176 and 186, the bit lines 188, and the conductive pads 182. The dielectric layer 190 may fill the trenches 186T. The dielectric layer 190 may include a dielectric material, e.g., silicon oxide, silicon nitride, silicon carbide, silicon oxynitride, high-k dielectric materials, or another suitable dielectric material. The dielectric layer 190 may be a single layer structure or a multilayer structure formed of sublayers of various dielectric materials. The dielectric layer 190 may be formed by deposition, such as CVD, PVD, ALD, spin coating, or another suitable deposition method.

Referring to FIG. 1AB, a trench (not separately shown) is formed through the dielectric layer 190 and the dielectric layer 186 over the conductive pad 187 to expose the conductive pad 187. A conductive material is deposited in the trench to form a conductive via 192 to be electrically coupled to the conductive pad 187. The conductive via 192 may have a material same as materials of the conductive pads 164, the bit lines 188 or the conductive pad 187, e.g., tungsten, or other conductive materials, such as copper, aluminum, silver, gold, titanium, titanium nitride, tantalum, tantalum nitride, or alloys thereof. A deposition process, such as a CVD process, using a conductive material of the conductive via 192, may be performed to improve gap-filling performance. In some embodiments, a planarization operation, e.g., CMP, is performed to remove excess materials of the conductive via 192 and planarize an upper surface of the conductive via 192.

FIG. 2 is a schematic top view of the semiconductor structure 100 in accordance with various embodiments of the present disclosure. FIGS. 1A to 1AB, shown as schematic cross-sectional views, are taken from sectional line AA of FIG. 2. In order to illustrate components more clearly, some features of the semiconductor structure 100 are omitted in FIG. 2. Referring to FIG. 2, the active regions 104 of the substrate 110, the word lines 148, and the bit lines 188 are shown. In some embodiments, the word lines 148 cross the bit lines 188 from the top-view perspective, and the data storage unit 124 (not shown in FIG. 2) is arranged directly above where the word lines 148 cross the bit lines 188 over the active regions 104. In some embodiments, each of the bit lines 188, the word line 148 and a source line (not separately shown) form a control unit of each memory cell, wherein the bit line 188 and the source line are coupled to the two electrode plates 114.

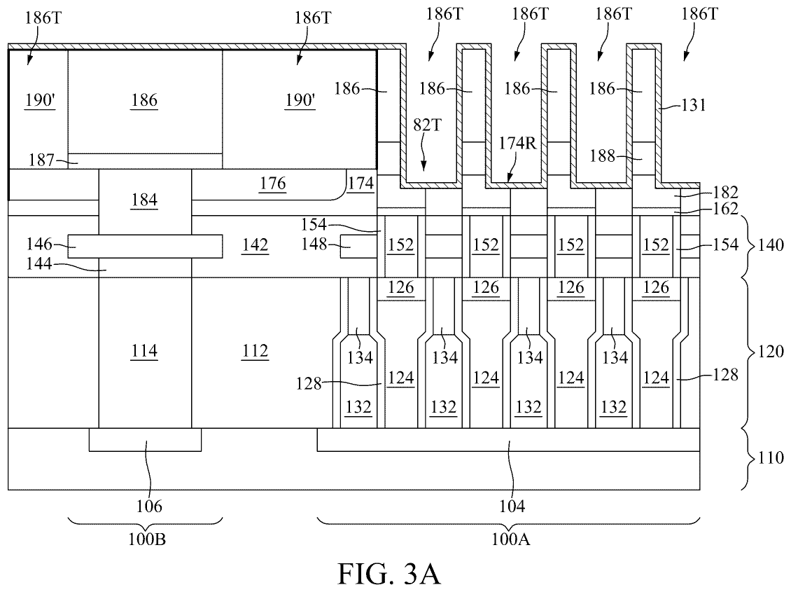

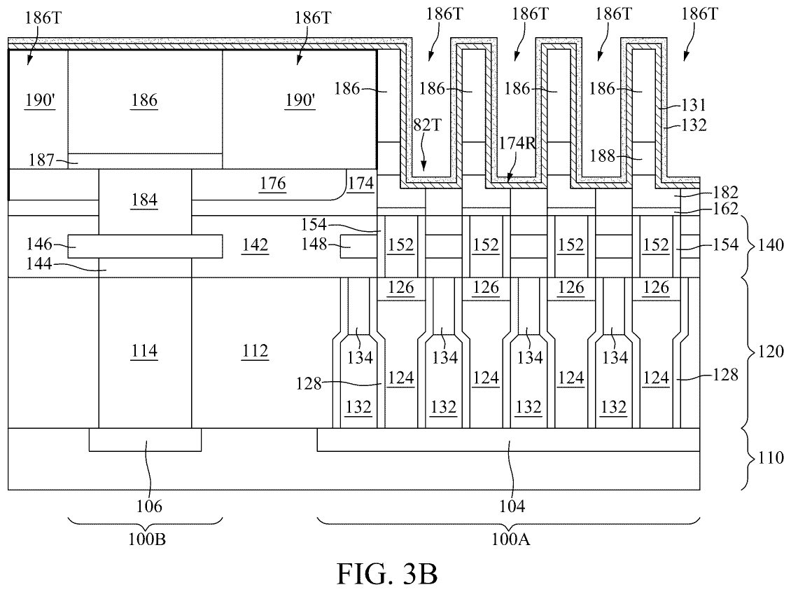

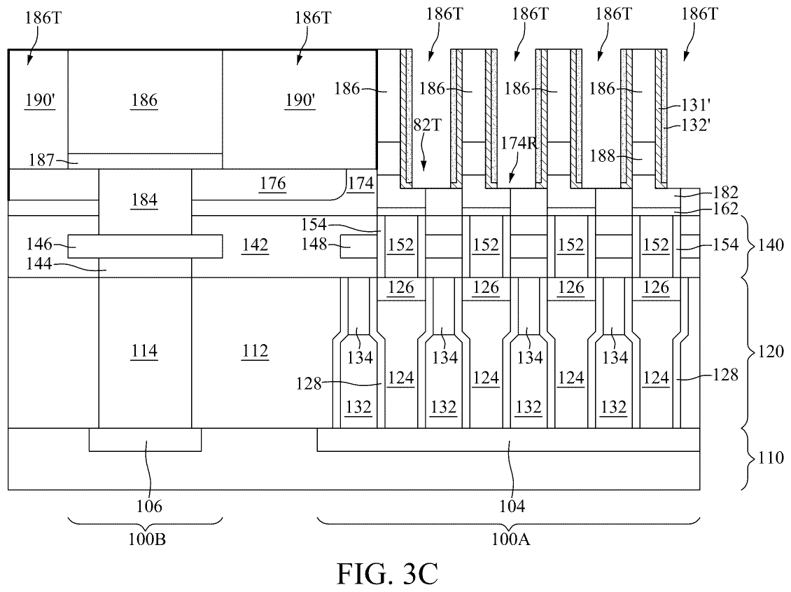

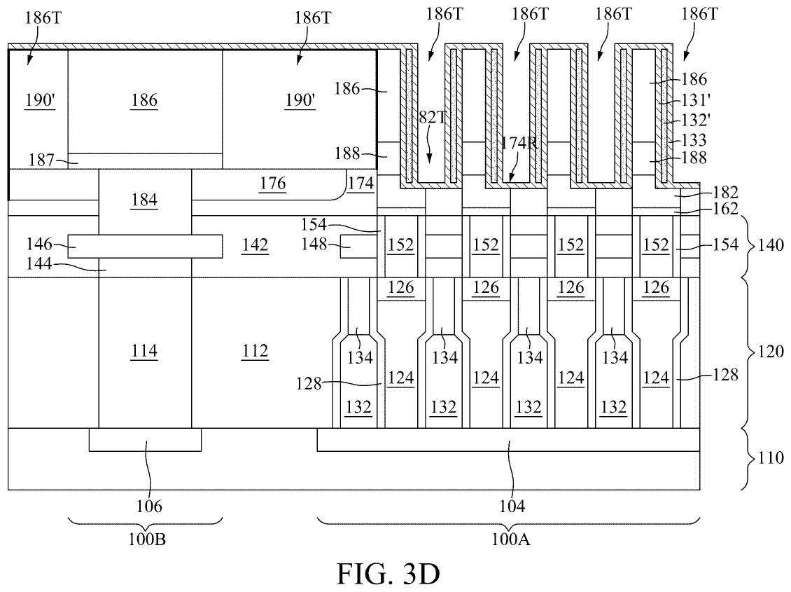

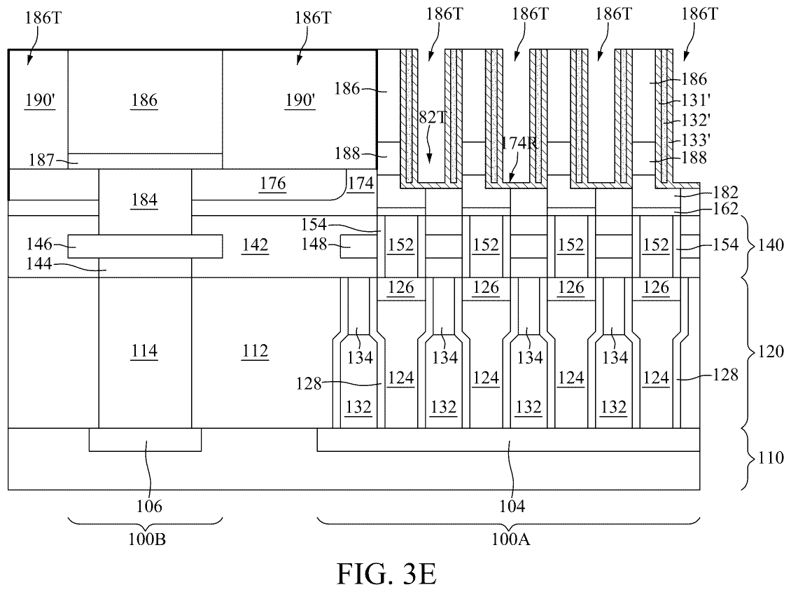

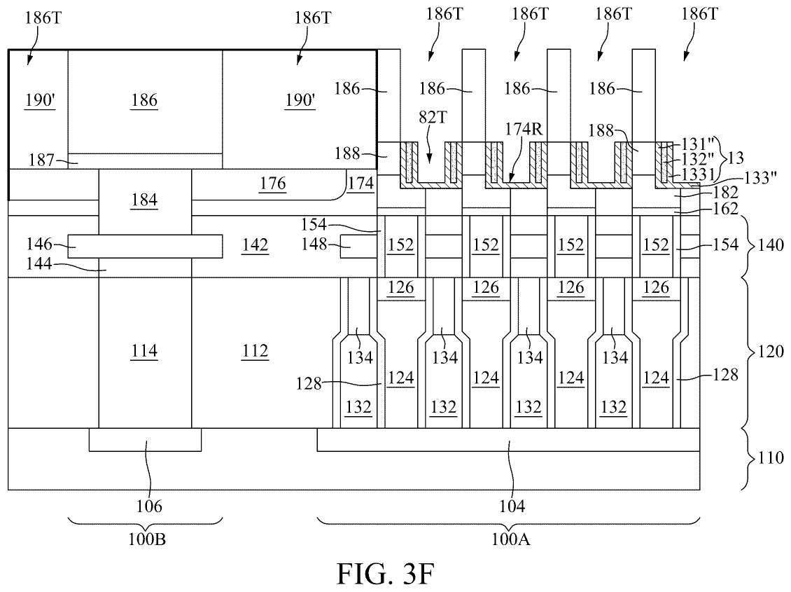

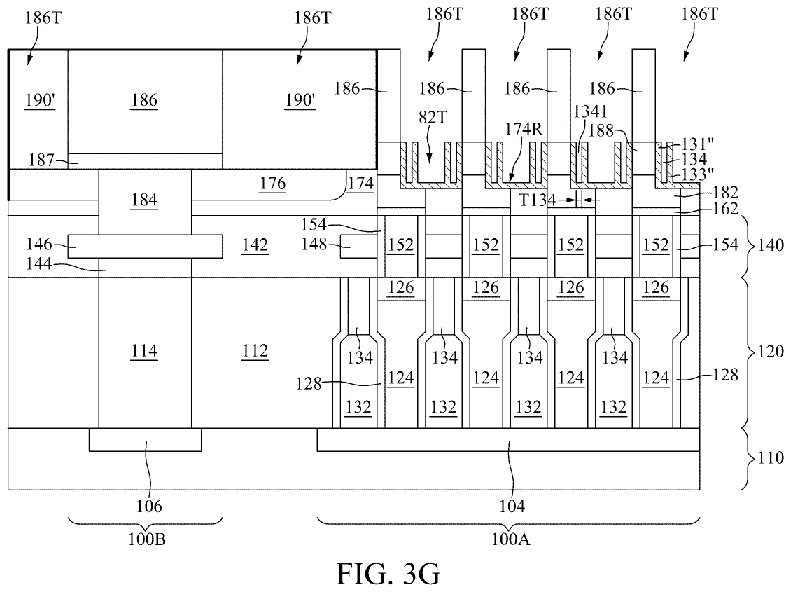

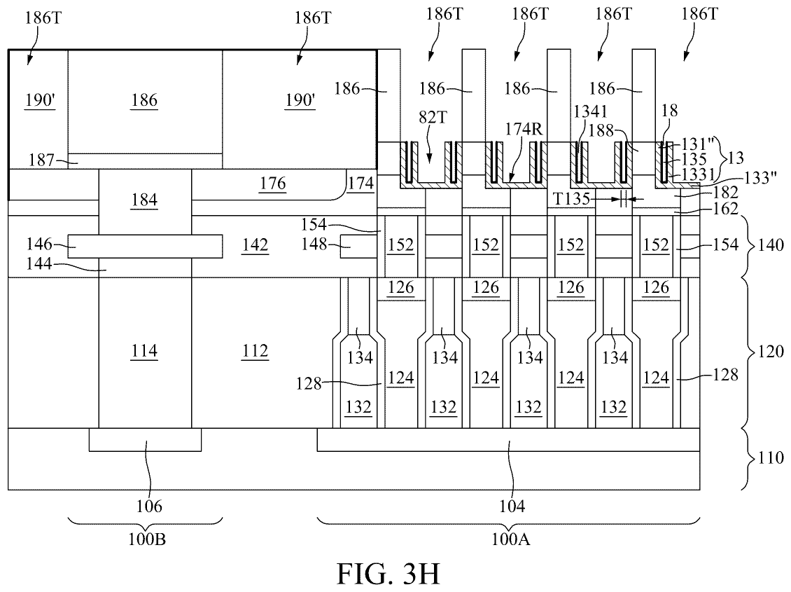

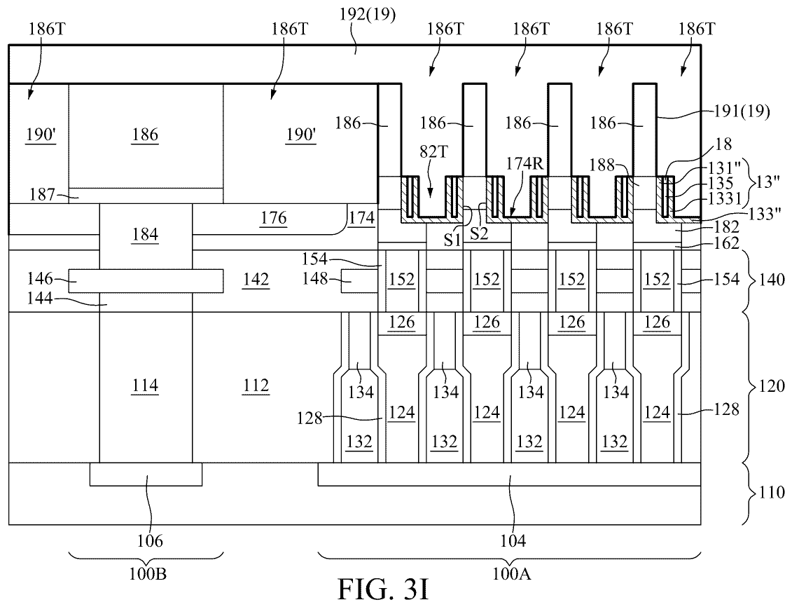

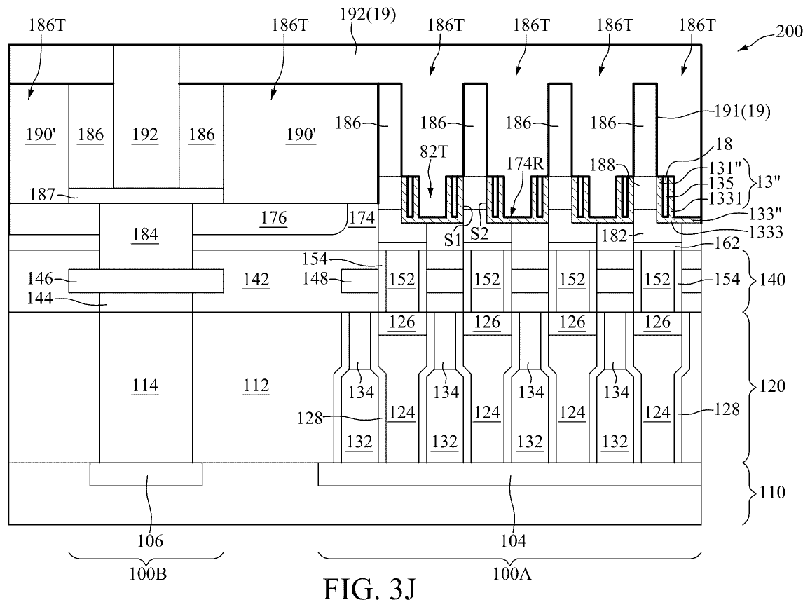

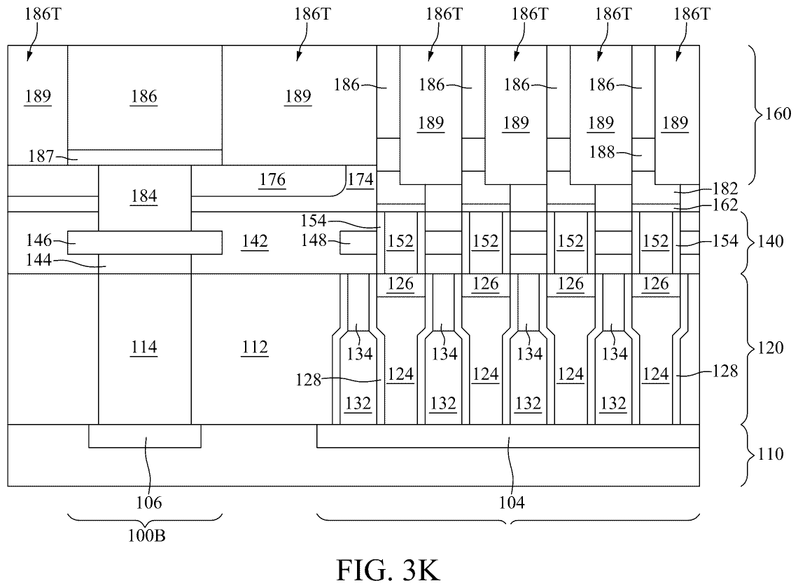

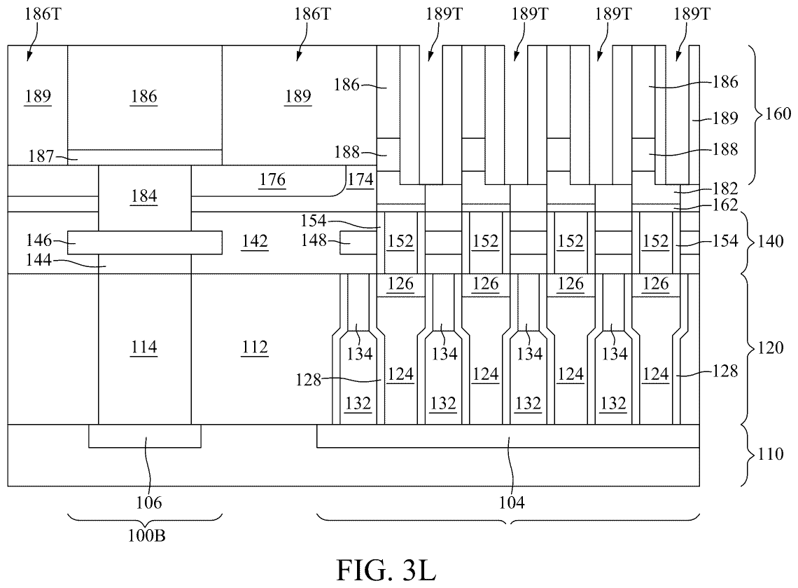

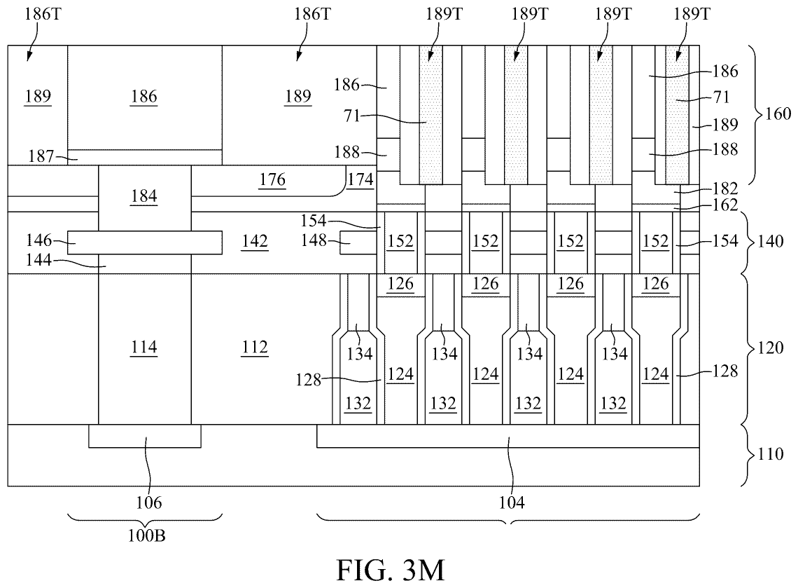

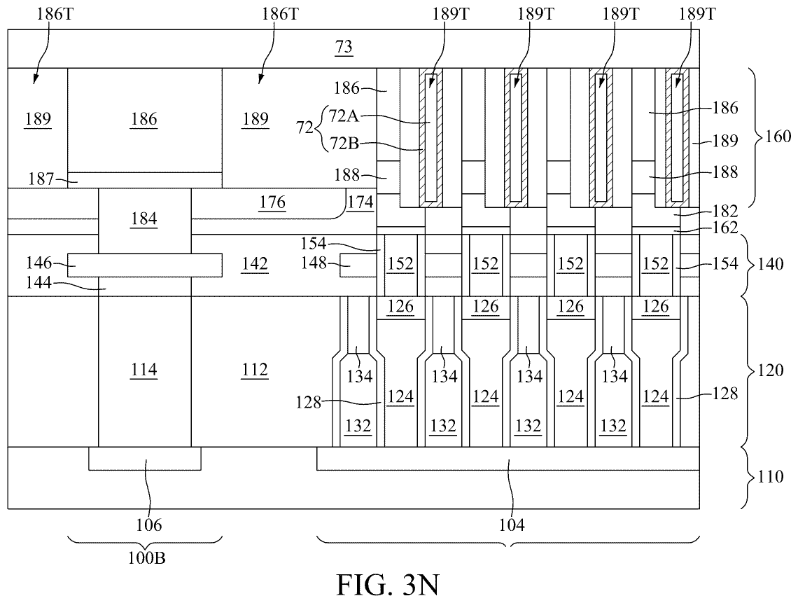

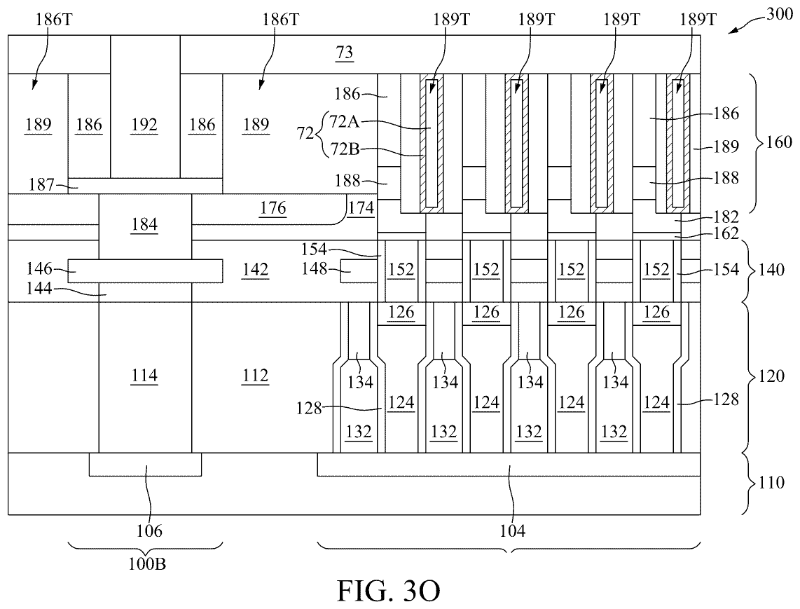

FIGS. 3A, 3B, 3C, 3D, 3E, 3F, 3G, 3H, 3I and 3J are schematic cross-sectional views of intermediate stages of the method 10 for forming a semiconductor structure 200, in accordance with various embodiments of the present disclosure. It should be noted that steps illustrated in FIGS. 3A to 3J are provided after the step illustrated in FIG. 1Z. In other words, the semiconductor structure 200 shares the intermediate stages of the method 10 illustrated in FIGS. 1A to 1Z, and descriptions of such steps are not repeated herein.

Referring to FIG. 3A, a first dielectric layer 131 is formed lining the trenches 186T, and formed on top surfaces of the dielectric layer 186 in the first region 100A and on a dielectric layer 190′ in the trenches 186T over the dielectric layers 174 and 176. In other words, the first dielectric layer 131 is formed on lateral sidewalls of the dielectric layer 186, the bit lines 188 and the conductive pads 182, on the top surfaces of the dielectric layer 186 and the dielectric layer 190′, and on bottom surfaces of the trenches 186T. In some embodiments, a portion of the first dielectric layer 131 has a profile conformal to the trenches 186T. In some embodiments, a thickness of the first dielectric layer 131 is in a range of 5 to 8 nanometers. In some embodiments, the dielectric layer 190′ may fill the trenches 186T over the dielectric layers 174 and 176. The dielectric layer 190′ may include a dielectric material, e.g., silicon oxide, silicon nitride, silicon carbide, silicon oxynitride, high-k dielectric materials, or another suitable dielectric material. The dielectric layer 190′ may be a single layer structure or a multilayer structure formed of sublayers of various dielectric materials. The dielectric layer 190′ may be formed by deposition, such as CVD, PVD, ALD, spin coating, or another suitable deposition method.

Referring to FIG. 3B, a sacrificial layer 132 is formed on the first dielectric layer 131. The sacrificial layer 132 may have a profile conformal to the first dielectric layer 131. In some embodiments, a thickness of the sacrificial layer 132 is in a range of 2 to 5 nanometers.

Referring to FIG. 3C, portions of the sacrificial layer 132 and the first dielectric layer 131 are respectively removed to form a sacrificial layer 132′ and a first dielectric layer 131′. In some embodiments, only vertical portions (i.e., portions extending along the Y direction) of the sacrificial layer 132 are left remaining, and only the portions of the first dielectric layer 131 covered by the sacrificial layer 132′ are left remaining. In some embodiments, the first dielectric layer 131′ is disposed only on lateral sidewalls (i.e., vertical sidewalls extending substantially along the Y direction) of the dielectric layer 186, the bit lines 188 and the conductive pads 182. Similarly, the sacrificial layer 132′ is also disposed only on lateral sidewalls (i.e., vertical sidewalls extending substantially along the Y direction) of the first dielectric layer 131′ disposed on the lateral sidewalls of the dielectric layer 186, the bit lines 188 and the conductive pads 182.

In some embodiments, a first directional etching operation is performed to remove horizontal portions (extending along the X direction) of the sacrificial layer 132. Next, a second directional etching operation is performed to remove portions of the first dielectric layer 131 exposed through the remaining sacrificial layer 132. Methods of formations of the sacrificial layer 132′ and the first dielectric layer 131′ are not limited herein. Any suitable technologies can be used, such as reactive ion etching (RIE), a lithographic operation, chemical mechanical polishing (CMP), another suitable operation, or a combination thereof, to form the structure shown in FIG. 3C. In some embodiments, a material of the sacrificial layer 132′ is different from that of the first dielectric layer 131′.

Referring to FIG. 3D, a second dielectric layer 133 is formed over and conformal to the bottom surfaces of the trenches 186T, the top surfaces of the dielectric layer 190′ and the dielectric layer 186 in the first region 100A, and lateral sidewalls of the bit lines 188, the first dielectric layer 131′, and the sacrificial layer 132′. In some embodiments, the second dielectric layer 133 contacts the exposed portions (i.e., the top surface) of the dielectric layer 186. In some embodiments, a thickness of the second dielectric layer 133 is in a range of 5 to 8 nanometers.

Referring to FIG. 3E, portions of the second dielectric layer 133 above the top surfaces of the dielectric layers 186 and 190′ are removed to form the dielectric layer 133′. The top surfaces of the first dielectric layer 131′, the sacrificial layer 132′, the second dielectric layer 133′, the dielectric layer 186 and the dielectric layer 190′ may be exposed. In some embodiments, a third directional etching operation, such as an anisotropic etching operation, may be performed to remove portions of the second dielectric layer 133′ above the top surfaces of the dielectric layers 186 and 190′.

Referring to FIG. 3F, portions of the first dielectric layer 131′, the sacrificial layer 132′ and the second dielectric layer 133′ above a top surface of the bit lines 188 are respectively removed to form a first dielectric layer 131″, a sacrificial layer 132″ and a second dielectric layer 133″. In some embodiments, top surfaces of the first dielectric layer 131″, the sacrificial layer 132″ and the second dielectric layer 133″ are coplanar. In some embodiments, a fourth directional etching operation, such as an anisotropic etching operation, may be performed to remove the portions of the first dielectric layer 131′, the sacrificial layer 132′ and the second dielectric layer 133′ above the top surface of the bit lines 188.

A spacer structure 13 including the first dielectric layer 131″, the sacrificial layer 132″, and a vertical portion 1331 of the second dielectric layer 133″ is formed. The spacer structure 13 is disposed on the lateral sidewalls of the bit line 188 and a portion of the conductive pad 182.

Referring to FIG. 3G, the sacrificial layer 132″ of the spacer structures 13 is removed, thereby forming a first gap 134 between the first dielectric layer 131″ and the second dielectric layer 133″. In some embodiments, the sacrificial layer 132″ is removed by a vapor etching operation. In some embodiments, vapor-phase hydrogen fluoride (HF) is used to remove the sacrificial layer 132″. The first gap 134 is defined by the first dielectric layer 131″ and the second dielectric layer 133″. In some embodiments, a thickness of the first dielectric layer 131″ and a thickness of the second dielectric layer 133″ are each reduced by 1 to 2 nanometers. In some embodiments, the first gap 134 has a width T134 in a range of 5 to 8 nanometers, which is equal to a distance between a vertical portion of the first dielectric layer 131″ and the second dielectric layer 133″. In some embodiments, the width T134 of the first gap 134 is substantially equal to a thickness of the sacrificial layer 132″. In some embodiments, a portion of the first dielectric layer 131″ and a portion of the second dielectric layer 133″ are consumed at points of contact with the sacrificial layer 132″ during the vapor etching operation, and thus the width T134 of the first gap 134 is greater than the thickness of the sacrificial layer 132″.

For ease of understanding, an interface of the first gap 134 and the first dielectric layer 131″ and an interface of the first gap 134 and the second dielectric layer 133″ are referred to as inner sidewalls 1341.

Referring to FIG. 3H, a spacer layer 18 is formed along the inner sidewall 1341, and the width T134 of the first gap 134 is reduced. In some embodiments, the spacer layer 18 is formed by atomic layer deposition on and along the inner sidewall 1341. The spacer layer 18 is made of dielectric materials. In some embodiments, the spacer layer 18 includes nitride, oxide, oxynitride, or a combination thereof. In some embodiments, the spacer layer 18 is made of a material same as a material of the first dielectric layer 131 and/or the second dielectric layer 133. In some embodiments, there is no distinct interface between the spacer layer 18 and the first dielectric layer 131″ if the spacer layer 18 and the first dielectric layer 131″ are made of a same material. In some embodiments, there is no distinct interface between the spacer layer 18 and the second dielectric layer 133″ if the spacer layer 18 and the second dielectric layer 133″ are made of a same material. In some embodiments, a thickness of the spacer layer 18 is in a range of 0.5 to 2 nanometers.

The spacer layer 18 shown in FIG. 3H is for illustration, but it is not intended to limit the spacer layer 18 of the present disclosure from being made of materials different from those of the first dielectric layer 131″ and the second dielectric layer 133″. In some embodiments, the first dielectric layer 131″, the second dielectric layer 133″, and the spacer layer 18 are made of same nitride materials. Thus, in such embodiments, there are no distinct interfaces between the spacer layer 18 and the first dielectric layer 131″, or between the spacer layer 18 and the second dielectric layer 133″. The spacer layer 18 is considered a part of the first dielectric layer 131″ and a part of the second dielectric layer 133″.

After the formation of the spacer layer 18, a second gap 135 is formed. The second gap 135 is formed from the first gap 134 and has a width T135 in a range of 3 to 5 nanometers. A combination of the first dielectric layer 131″, the spacer layer 18, the second gap 135 and the vertical portion 1331 of the second dielectric layer 133″ is referred to as a spacer structure 13″. It should be noted that the spacer layer 18 is formed with a thickness that depends on the width T135 of the second gap 135. In some embodiments, the width T135 is 1 to 4 nanometers less than the width T134.

Referring to FIG. 3I, a seal layer 19 is formed over the spacer structure 13″, the second dielectric layer 133″, the dielectric layer 186 and the dielectric layer 190′. In some embodiments, the seal layer 19 is a multi-layered structure. In some embodiments, the seal layer 19 includes a linear layer 191 and a planar layer 192. In some embodiments, the linear layer 191 is conformal to a profile of the spacer structure 13″ and the dielectric layers 186 and 190′. In some embodiments, the linear layer 191 is formed by a chemical vapor deposition (CVD), which seals a top of the second gap 135 without filling in the second gap 135. In some embodiments, the linear layer 191 is formed with a high deposition rate in order to have a less condensed structure and to prevent filling in the second gap 135. In some embodiments, the planar layer 192 is formed by an atomic layer deposition (ALD) in order to avoid formation of voids, and the planar layer 192 covers an entire surface over the substrate 110.

Referring to FIG. 3J, a trench (not separately shown) is formed through the seal layer 19 and the dielectric layer 186 over the conductive pad 187 to expose the conductive pad 187. A conductive material is deposited in the trench to form a conductive via 192 to be electrically coupled to the conductive pad 187. The conductive via 192 may have a material same as materials of the conductive pads 164, the bit lines 188 or the conductive pad 187, e.g., tungsten, or other conductive materials such as copper, aluminum, silver, gold, titanium, titanium nitride, tantalum, tantalum nitride, or alloys thereof. A deposition process, such as a CVD process, using a conductive material of the conductive via 192, may be performed to improve gap-filling performance. In some embodiments, a planarization operation, e.g., CMP, is performed to remove excess materials of the conductive via 192 and planarize an upper surface of the conductive via 192. After the conductive via 192 is formed through the seal layer 19 and the dielectric layer 186 over the conductive pad 187, and is electrically coupled to the conductive pad 187, the semiconductor structure 200 is obtained.

FIGS. 3K, 3L, 3M, 3N and 3O are schematic cross-sectional views of intermediate stages of the method 10 for forming a semiconductor structure 300, in accordance with various embodiments of the present disclosure. It should be noted that the steps illustrated in FIGS. 3K to 3O are provided after the step illustrated in FIG. 1Z. In other words, the semiconductor structure 300 shares the intermediate stages of the method 10 illustrated in FIGS. 1A to 1Z, and descriptions of such steps are not repeated herein.

Referring to FIG. 3K, an inter-layer dielectric (ILD) layer 189 is deposited over the dielectric layers 174, 176 and 186, the bit lines 188, and the conductive pads 182. The ILD layer 189 may fill the trenches 186T. In some embodiments, the ILD layer 189 is formed by a deposition process, such as a CVD process, a flowable CVD (FCVD) process, an HDPCVD process, an ALD process, a spin-coating process, another applicable process, or a combination thereof. In some embodiments, the ILD layer 189 is made of silicon oxide, silicon nitride, silicon oxynitride, phosphosilicate glass (PSG), borophosphosilicate glass (BPSG), low-k dielectric material, and/or other applicable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), and polyimide. After the deposition process for forming the ILD layer 189 is performed, a planarization process may be performed to remove a portion of the ILD layer 189, thereby causing a top surface of the ILD layer 189 to be coplanar with a top surface of the dielectric layer 186.

Referring to FIG. 3L, a trench 189T is formed in the ILD layer 189. The formation of the trench 189T may include forming an opening (not shown in the drawings) in the ILD layer 189 by a lithographic process and performing an etching process through the opening to form the trench 189T.

Referring to FIG. 3M, a reinforcement pillar 71 is formed in the ILD layer 189 by depositing an energy-removable material in the trench 189T. The energy-removable material may be deposited over the dielectric layer 186 and the ILD layer 189, and in the trench 189T. Next, a planarization process, such as a chemical mechanical polishing (CMP) process, may be performed to remove portions of the energy-removable material above the top surface of the dielectric layer 186 (or above a top surface of the ILD layer 189). In some embodiments, the energy-removable material includes a thermal decomposable material. In other embodiments, the energy-removable material includes a photonic decomposable material, an e-beam decomposable material, or another applicable energy decomposable material. In some embodiments, materials of the energy-removable material include a base material and a decomposable porogen material that is substantially removed when exposed to an energy source (e.g., heat). In some embodiments, the base material includes hydrogen silsesquioxane (HSQ), methylsilsesquioxane (MSQ), porous polyarylether (PAE), porous SiLK, or porous silicon oxide (SiO₂), and the decomposable porogen material includes a porogen organic compound, which can, in subsequent processes, provide porosity to a space originally occupied by the energy-removable layer.

Referring to FIG. 3N, a capping dielectric layer 73 is formed over the reinforcement pillar 71, the dielectric layer 186 and the ILD layer 189, and the reinforcement pillar 71 is transformed into a dielectric isolation structure 72 including a liner layer 72B enclosing an air gap 72A. In some embodiments, the capping dielectric layer 73 is formed by chemical vapor deposition, atomic layer deposition, or another applicable deposition process. In some embodiments, the capping dielectric layer 73 may be made of a dielectric material, such as silicon oxide, silicon nitride, silicon oxynitride, or the like. In some embodiments, a thermal process is performed to transform the reinforcement pillar 71 into the dielectric isolation structure 72.

Referring to FIG. 3O, a trench (not separately shown) is formed through the capping dielectric layer 73 and the dielectric layer 186 over the conductive pad 187 to expose the conductive pad 187. A conductive material is deposited in the trench to form a conductive via 192 to be electrically coupled to the conductive pad 187. The conductive via 192 may have a material same as materials of the conductive pads 164, the bit lines 188 or the conductive pad 187, e.g., tungsten, or other conductive materials, such as copper, aluminum, silver, gold, titanium, titanium nitride, tantalum, tantalum nitride, or alloys thereof. A deposition process, such as a CVD process, using a conductive material of the conductive via 192, may be performed to improve gap-filling performance. In some embodiments, a planarization operation, e.g., CMP, is performed to remove excess materials of the conductive via 192 and planarize an upper surface of the conductive via 192. After the conductive via 192 is formed through the capping dielectric layer 73 and the dielectric layer 186 over the conductive pad 187, and is electrically coupled to the conductive pad 187, the semiconductor structure 300 is obtained.

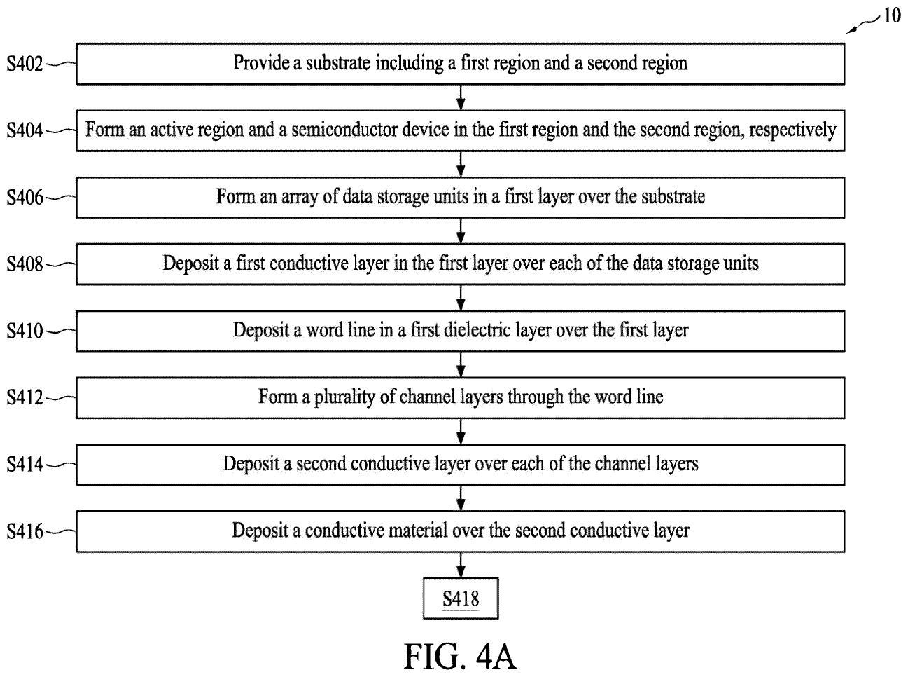

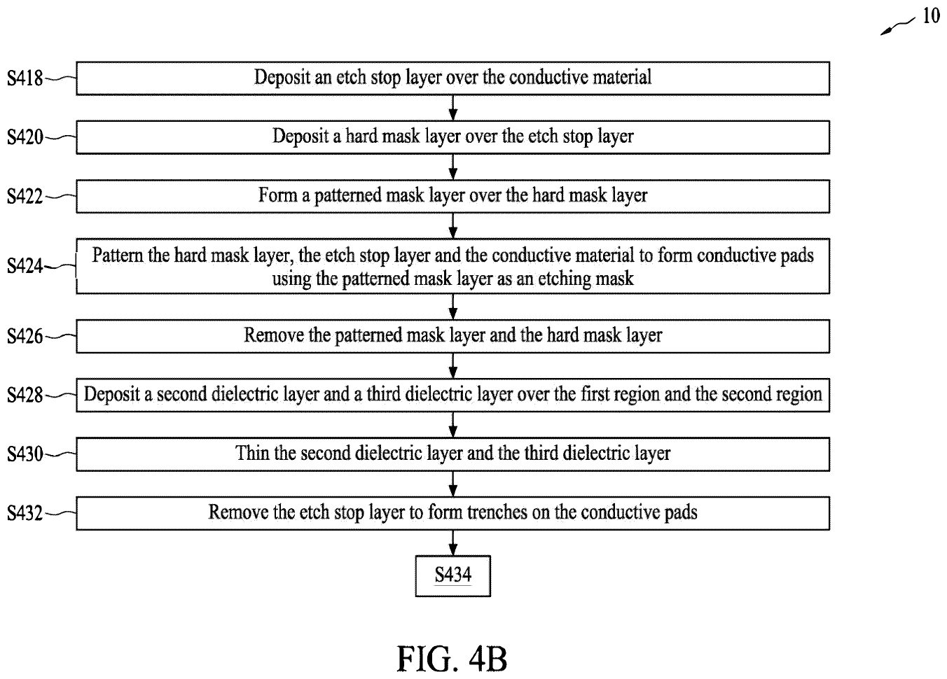

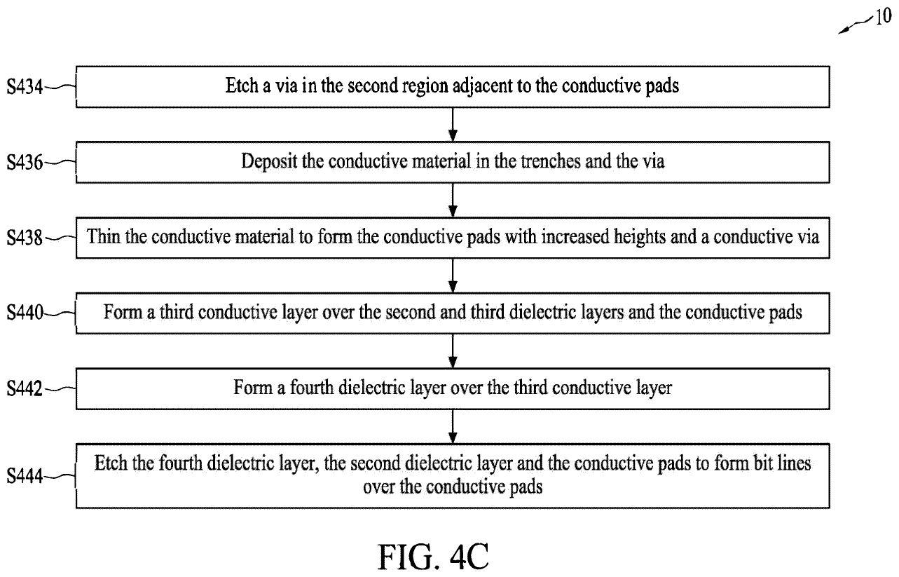

FIGS. 4A, 4B and 4C show schematic flowcharts of a method 10 of forming a semiconductor structure, in accordance with some embodiments. It should be understood that additional steps can be provided before, during, and after the steps shown in FIGS. 4A to 4C, and that some of the steps described below can be replaced or eliminated in additional embodiments of the method 10. The steps may be performed independently, and the order of the steps may be interchangeable. The semiconductor structure described with reference to FIGS. 4A to 4C may be same as or similar to the semiconductor structure 100. The flowcharts of the method 10 are illustrated with reference to aforementioned FIGS. 1A to 1Z.

Referring to FIGS. 4A and 1A, in step S402, a substrate 110 including a first region 100A and a second region 100B is provided. In some embodiments, the first region 100A is a memory array region. In some embodiments, the second region 100B is a peripheral region. The second region 100B may be arranged adjacent to the first region 100A, and may laterally surround the first region 100A.

Referring to FIGS. 4A and 1A, in step S404, an active region 104 and a semiconductor device 106 are formed in the first region 100A and the second region 100B, respectively. The active region 104 may be formed of doped region with an n-type or p-type dopant. The semiconductor device 106 may include one or more active devices, e.g., transistors or the like, or one or more passive devices, e.g., resistors, capacitors, inductors, diodes, fuses, or the like.

Still referring to FIGS. 4A and 1A, in step S406, an array of data storage units 124, are formed in a first layer 120 over the substrate 110. In some embodiments, each of the data storage units 124 is formed of capacitors to store data.

Still referring to FIGS. 4A and 1A, in step S408, a first conductive layer 126 is deposited in the first layer 120 over each of the data storage units 124. The first conductive layer 126 may include ITO, IWO, or another suitable conductive oxide material.

Referring to FIGS. 4A and 1B, in step S410, a word line 148 is deposited in a first dielectric layer 142 over the first layer 120.

Referring to FIG. 4A, and FIGS. 1C to 1G, in step S412, a plurality of channel layers 152 are formed through the word line 148. In some embodiments, a plurality of insulating films 154 are formed on the sidewalls of each of the channel layers 152. The channel layers 152 are electrically coupled to the underlying first conductive layer 126.

Referring to FIGS. 4A and 1H, in step S414, a second conductive layer 161 is deposited over each of the channel layers 152. The second conductive layer 161 may include ITO, IWO, or another suitable conductive oxide material.

Referring to FIGS. 4A and 1I, in step S416, a conductive material 163 is deposited over the second conductive layer 161. In some embodiments, the conductive material 163 includes tungsten. In some embodiments, the conductive material 163 includes aluminum, silver, gold, titanium, titanium nitride, tantalum, tantalum nitride, alloys thereof, or the like.

Referring to FIGS. 4B and 1J, in step S418, an etch stop layer 165 is deposited over the conductive material 163. The etch stop layer 165 may include silicon nitride, silicon carbide, high-k dielectric materials or another suitable material.

Referring to FIGS. 4B and 1K, in step S420, a hard mask layer 167 is deposited over the etch stop layer 165. In some embodiments, the hard mask layer 167 is substantially formed of elementary carbon.

Referring to FIG. 4B, and FIGS. 1L and 1M, in step S422, a patterned mask layer 170 is deposited over the hard mask layer. The formation of the patterned mask layer 170 may comprise depositing a photoresist or a mask layer 169 over an upper surface of the hard mask layer 167 as shown I FIG. 1L, and performing one or more patterning operations on the photoresist 169. Thereby the photoresist 169 is etched into a patterned photoresist or a patterned mask layer 170. The patterned mask layer 170 may include an under layer and a DARC. In some embodiments, the patterned mask layer 170 includes a pattern of a plurality of conductive pads or landing pads.

Referring to FIGS. 4B and 1M, in step S424, the hard mask layer 167, the etch stop layer 165 and the conductive materials 163 and 161 are patterned to form a patterned hard mask layer 168, a patterned etch stop layer 166, conductive pads 164 and a patterned second conductive layer 162, respectively, using the patterned mask layer 170 as an etching mask. In some embodiments, the etching operations for patterning the hard mask layer 167, the etch stop layer 165 and the conductive material 163 are performed sequentially or during a single etching operation.

Referring to FIGS. 4B and 1N, in step S426, the patterned mask layer 170 and the hard mask layer 168 are removed. The removal of the patterned mask layer 170 and the hard mask layer 168 may include an etching operation, e.g., a dry etch, a wet etch, an RIE, or the like.

Referring to FIG. 4B, and FIGS. 1Q and 1R, in step S428, a second dielectric layer 174 and a third dielectric layer 176 are deposited over the first region 100A and the second region 100BN. In some embodiments, the second dielectric layer 174 and the third dielectric layer 176 are formed using different deposition methods, e.g., the second dielectric layer 174 is formed using ALD, and the third dielectric layer 176 is formed using CVD. The third dielectric layer 176 covers the entire second dielectric layer 174.

Referring to FIGS. 4B and 1S, in step S430, the second dielectric layer 174 and the third dielectric layer 176 are thinned. The thinning operation may include a CMP operation. In some embodiments, during the thinning operation, the second dielectric layer 174 is caused to be level with the third dielectric layer 176. In some embodiments, during the thinning operation, upper surfaces of the etch stop layer 166 are caused to be level with the second dielectric layer 174.

Referring to FIGS. 4B and 1T, in step S432, the etch stop layer 166 is thinned to form trenches 174T on the conductive pads 164. In some embodiments, during the thinning operation, portions of the etch stop layer 166 are removed from upper surfaces of the conductive pads 164 to expose the upper surfaces of the conductive pads 164. The thinning operation may be performed using a dry etch, a wet etch, an RIE or the like.

Referring to FIGS. 4C and 1U, in step S434, a via 176T is etched in the second region 100B adjacent to the conductive pads 164. The via 176T may extend through the second dielectric layer 174 and the third dielectric layer 176 and partly through the first dielectric layer 142.

Referring to FIGS. 4C and 1V, in step S436, a conductive material 178 is deposited in the trenches 174T and the via 176T. In some embodiments, the conductive material 178 fills the trenches 174T and the via 176T, and extends over the second dielectric layer 174 and the third dielectric layer 176.

Referring to FIGS. 4C and 1W, in step S438, the conductive material 178 is thinned to form the conductive pads 182 with increased heights and a conductive via 184 in the via 176T. In some embodiments, the thinning operation includes CMP or mechanical grinding.

Referring to FIGS. 4C and 1X, in step S440, a third conductive layer 185 is formed over the second dielectric layer 174, the third dielectric layer 176 and the conductive pads 182. In some embodiments, the third conductive layer 185 covers the second dielectric layer 174 and the third dielectric layer 176 and the conductive pads 182.

Referring to FIGS. 4C and 1Y, in step S442, a fourth dielectric layer 186 is formed over the third conductive layer 185. In some embodiments, the fourth dielectric layer 186 covers the third conductive layer 185.

Referring to FIGS. 4C and 1Z, in step S444, the fourth dielectric layer 186, the second dielectric layer 174 and the conductive pads 182 are etched to form a plurality of bit lines 188 over the conductive pads 182. In some embodiments, the bit lines 188 are electrically coupled to the data storage units 124 through the conductive pads 182, the first conductive layer 126, the channel layer 152, and the patterned second conductive layer 162.

The proposed planarization method for the memory cells provides advantages. Since some characteristics of the CMP, such as the surface roughness, are substantially proportional to the etched thickness of the CMP, a final surface uniformity may not meet the design requirement when a material layer that needs to be planarized, e.g., the conductive pad 164, has a relatively low thickness or height as compared to the etched heights of the material layers thinned by CMP. The surface roughness may cause over-polishing defects in some of the conductive pads, while causing under-polishing defects in some other conductive pads at the same time. Furthermore, such under-polishing and over-polishing may occur in a single semiconductor wafer.

By arranging the proposed etch stop layer, e.g., the etch stop layer 166, over the conductive pads, a tolerance of the surface roughness of the CMP operation can be greatly increased. It is easier to allow the CMP grinding to stop at the etch stop layers without consuming the underlying conductive pads or otherwise leaving more dielectric residues on the conductive pads. Furthermore, an end-point detection scheme during the CMP can be performed more effectively due to the presence of the etch stop layer. As a result, a process window of the planarization operation is enlarged, and the conductive pads can be deposited and planarized with high reliability and uniformity. Robustness and yield of the semiconductor memory structure can thereby be improved.

In accordance with some embodiments, in the semiconductor structure provided in this disclosure, an air gap is disposed in a spacer structure along a bit line, and a dielectric isolation structure including an air gap is disposed between a pair of bit lines. The semiconductor structure can provide a better electrical performance and enhanced reliability for semiconductor devices. In addition, the method for fabricating the semiconductor structure can minimize the additional cost in manufacturing.

One aspect of the present disclosure provides a semiconductor structure. The semiconductor structure includes a data storage unit disposed in a first dielectric layer; a word line disposed in a second dielectric layer over the first dielectric layer; an array of conductive pads disposed over the second dielectric layer; a bit line disposed over the conductive pads; a third dielectric layer disposed over the second dielectric layer; and a fourth dielectric layer disposed over the third dielectric layer.

One aspect of the present disclosure provides a semiconductor structure. The semiconductor structure includes a data storage unit disposed in a first dielectric layer; a word line disposed in a second dielectric layer over the first dielectric layer; an array of conductive pads disposed over the second dielectric layer; a bit line disposed over the conductive pads; a third dielectric layer disposed over the second dielectric layer; a fourth dielectric layer disposed over the third dielectric layer; a fifth dielectric layer disposed on the bit line, and disposed over the third dielectric layer and the fourth dielectric layer; a sixth dielectric layer disposed between a pair of the fifth dielectric layers, and over the third dielectric layer and the fourth dielectric layer; and a conductive line disposed in the second dielectric layer.

One aspect of the present disclosure provides a method for fabricating a semiconductor structure. The method includes providing a substrate including a first region and a second region adjacent to the first region; forming a first layer over the first region and the second region of the substrate, wherein the first layer comprises: a first dielectric layer across the first region and the second region of the substrate, and a data storage unit disposed in the first dielectric layer; forming a second layer on the first layer and over the first region and the second region of the substrate, wherein the second layer comprises: a second dielectric layer across the first region and the second region of the substrate, and a word line disposed in the second dielectric layer; and forming a third layer on the second layer and over the first region and the second region of the substrate, wherein the third layer comprises: a third dielectric layer disposed over the second layer, and over the first region and the second region of the substrate, a fourth dielectric layer disposed over the second layer, a fifth dielectric layer disposed over the fourth dielectric layer over the second region of the substrate; a sixth dielectric layer disposed between a pair of the third dielectric layers; a bit line disposed below the third dielectric layer; a conductive layer disposed below the bit line; and a conductive pad disposed between the bit line and the conductive pad.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods or steps, presently existing or later to be developed, that perform substantially the same function or achieve substantially the same result as the corresponding embodiments described herein, may be utilized in accordance with the present disclosure. Accordingly, the appended claims are intended to include within their scope such processes, machines, manufacture, compositions of matter, means, methods and steps.

What is claimed is:

1. A semiconductor structure, comprising:
a data storage unit disposed in a first dielectric layer;
a word line disposed in a second dielectric layer over the first dielectric layer;
an array of conductive pads disposed over the second dielectric layer;
a bit line disposed over the conductive pads;
a third dielectric layer disposed over the second dielectric layer; and
a fourth dielectric layer disposed over the third dielectric layer.

2. The semiconductor structure of claim 1, further comprising a spacer structure disposed on sidewalls of the bit line, wherein the spacer structure includes a second air gap.

3. The semiconductor structure of claim 2, wherein the second air gap is sandwiched by a first spacer dielectric layer and a vertical portion of a second spacer dielectric layer, and the second air gap is sealed by a seal layer.

4. The semiconductor structure of claim 3, wherein the second air gap is formed by disposing a spacer layer in a first air gap between the first spacer dielectric layer and the second spacer dielectric layer.

5. The semiconductor structure of claim 4, wherein the first air gap is formed by removing a sacrificial layer disposed between the first spacer dielectric layer and the second spacer dielectric layer.

6. The semiconductor structure of claim 5, further comprising a fifth dielectric layer disposed on the bit line, and disposed over the third dielectric layer and the fourth dielectric layer; and a sixth dielectric layer disposed between a pair of the fifth dielectric layers over the third dielectric layer and the fourth dielectric layer.

7. The semiconductor structure of claim 6, wherein the seal layer includes a linear layer and a planar layer, wherein the linear layer is disposed over the spacer structure, a horizontal portion of the second spacer dielectric layer, the dielectric layer and the sixth dielectric layer, and the planar layer is disposed over the linear layer.

8. The semiconductor structure of claim 7, further comprising a conductive via extending through the seal layer and the fifth dielectric layer, wherein the conductive via is connected to a conductive pad over the third and fourth dielectric layers.

9. The semiconductor structure of claim 4, wherein a width of the second air gap is less than a width of the first air gap.

10. The semiconductor structure of claim 9, wherein the spacer layer is made of a material same as a material of the first dielectric layer and the second dielectric layer.
